(19) United States
(12) Patent Application Publication
(10) Pub. No.: US 2024/0292518 A9
(43) Pub. Date: Aug. 29, 2024

(54) Component Carrier For Waveguide Applications

(71) Applicant: AT&S Austria Technologie & Systemtechnik AG, Leoben (AT)

(72) Inventors: Heinrich Trischler, Trofaiach (AT); Erich Schlaffer, St. Lorenzen (AT); Markus Leitgeb, Trofaiach (AT); Sebastian Sattler, Graz (AT); Simon Pressler, Graz (AT)

(21) Appl. No.: 18/253,341

(22) PCT Filed: Nov. 11, 2021
(86) PCT No.: PCT/EP2021/081405

§ 371 Date: May 17, 2023

(30) Foreign Application Priority Data
Nov. 18, 2020 (DE) 10 2020 130 453.6
Apr. 30, 2021 (DE) 10 2021 111 273.7
Oct. 28, 2021 (EP) 21205396.1

(51) Int. Cl. H05K 1/02; H05K 3/46

(52) U.S. Cl. CPC H05K 1/0237; H05K 1/0284; H05K 3/4697; H05K 2201/09036; H05K 2201/09981; H05K 2201/10098

(57) ABSTRACT

A component carrier which includes a stack having at least one electrically conductive layer structure, at least one electrically insulating layer structure, and a recess being at least partially formed in the stack, optionally having an electrically conductive coating, and being configured as waveguide, wherein a plurality of edges delimiting the recess are formed by electrically conductive material of the at least one electrically conductive layer structure and/or of the optional electrically conductive coating.

### CROSS-REFERENCE TO RELATED APPLICATIONS

This application is the U.S. national phase of International Application No. PCT/EP2021/081405 filed Nov. 11, 2021, which designated the U.S. and claims priority to European Patent Application No. 21205396.1, filed Oct. 28, 2021, DE 10 2021 111 273.7, filed on Apr. 30, 2021, and DE 10 2020 130 453.6, filed on Nov. 18, 2020, the entire contents of each of which are hereby incorporated herein by reference.

### TECHNICAL FIELD

The disclosure relates to component carriers, to methods of manufacturing a component carrier, and to a method of use.

### TECHNOLOGICAL BACKGROUND

In the context of growing product functionalities of component carriers equipped with one or more electronic components and increasing miniaturization of such electronic components as well as a rising number of electronic components to be mounted on the component carriers such as printed circuit boards, increasingly more powerful array-like components or packages having several electronic components are being employed, which have a plurality of contacts or connections, with ever smaller spacing between these contacts. Removal of heat generated by such electronic components and the component carrier itself during operation becomes an increasing issue. At the same time, component carriers shall be mechanically robust and electrically reliable so as to be operable even under harsh conditions.

Moreover, artefacts may occur when high-frequency signals propagating along wiring structures of a component carrier mix or multiply with each other to generate distorted signals. This undesired phenomenon may be denoted as passive intermodulation (PIM) and may deteriorate signal transmission over a component carrier. Passive intermodulation can substantially degrade the overall performance of mobile communication systems, etc.

### SUMMARY

There may be a need for to provide a component carrier with high performance, in particular in terms of signal transmission.

According to an exemplary embodiment of a first aspect of the disclosure, a component carrier is provided which comprises a stack comprising at least one electrically conductive layer structure and at least one electrically insulating layer structure, and a recess, in particular a cavity, being at least partially formed in the stack, having optionally an electrically conductive coating (which may partially or entirely cover one or more walls delimiting the recess), and being configured as a waveguide, wherein a plurality of edges delimiting the recess are formed by electrically conductive material of the at least one electrically conductive layer structure and/or of the optional electrically conductive coating.

According to another exemplary embodiment of the first aspect of the disclosure, a method of manufacturing a component carrier is provided, wherein the method comprises providing a stack comprising at least one electrically conductive layer structure and at least one electrically insulating layer structure, forming a recess, in particular a cavity, at least partially in the stack, wherein a plurality of edges delimiting the recess are formed by electrically conductive material of the at least one electrically conductive layer structure and/or of an optional electrically conductive coating, and configuring said recess as a waveguide.

According to an exemplary embodiment of a second aspect of the disclosure, a component carrier is provided, wherein the component carrier comprises at least one electrically conductive layer structure and at least one electrically insulating layer structure, and a recess being at least partially formed in the stack and being configured as waveguide, wherein a width of the recess varies along a length of the recess by not more than 75 μm.

According to another exemplary embodiment of the second aspect of the disclosure, a method of manufacturing a component carrier is provided, wherein the method comprises providing a stack comprising at least one electrically conductive layer structure and at least one electrically insulating layer structure, forming a recess at least partially in the stack, wherein a width of the recess varies along a length of the recess by not more than 75 μm, and configuring said recess as a waveguide.

According to an exemplary embodiment of a third aspect of the disclosure, a component carrier is provided, wherein the component carrier comprises a stack comprising at least one electrically conductive layer structure and at least one electrically insulating layer structure, a recess being at least partially formed in the stack and being configured as a waveguide, a wiring structure forming part of the at least one electrically conductive layer structure and being arranged on top of said recess, and a ridge surrounding the recess, wherein the wiring structure is electrically coupled with the waveguide via the ridge.

According to another exemplary embodiment of the third aspect of the disclosure, a method of manufacturing a component carrier is provided, wherein the method comprises providing a stack comprising at least one electrically conductive layer structure and at least one electrically insulating layer structure, forming a recess at least partially in the stack, configuring said recess as a waveguide, forming a wiring structure as part of the at least one electrically conductive layer structure on top of said recess, and forming a ridge to surround the recess and so that the wiring structure is electrically coupled with the waveguide via the ridge.

According to an exemplary embodiment of a fourth aspect of the disclosure, a component carrier is provided, wherein the component carrier comprises a stack comprising at least one electrically conductive layer structure and at least one electrically insulating layer structure, wherein at least one of the at least one electrically insulating layer structure is made of a poorly adhesive structure, and a metallic electroless plating structure formed on a surface of the stack apart from the poorly adhesive structure.

According to another exemplary embodiment of the fourth aspect of the disclosure, a method of manufacturing a component carrier is provided, wherein the method comprises providing a stack comprising at least one electrically conductive layer structure and at least one electrically insulating layer structure, wherein at least one of the at least one electrically insulating layer structure is made of a poorly adhesive structure, exposing the poorly adhesive structure, and forming a metallic structure by electroless plating selectively on a surface of the stack apart from the exposed poorly adhesive structure.

According to an exemplary embodiment of a fifth aspect of the disclosure, a component carrier is provided, wherein the component carrier comprises a stack comprising at least one electrically conductive layer structure and at least one electrically insulating layer structure, and a recess being at least partially formed in the stack and being configured as a waveguide, and an electrically conductive coating on at least part of sidewalls of the stack which laterally delimit the recess, wherein the electrically conductive coating is curved outwardly on an upper end of the sidewalls.

According to another exemplary embodiment of the fifth aspect of the disclosure, a method of manufacturing a component carrier is provided, wherein the method comprises providing a stack comprising at least one electrically conductive layer structure and at least one electrically insulating layer structure, forming a recess at least partially in the stack, configuring said recess as a waveguide, and forming an electrically conductive coating on at least part of sidewalls of the stack which laterally delimit the recess, wherein the electrically conductive coating is curved outwardly on an upper end of the sidewalls.

According to an exemplary embodiment of a sixth aspect of the disclosure, a component carrier is provided which comprises a stack comprising at least one electrically conductive layer structure and at least one electrically insulating layer structure, a recess being at least partially formed in the stack, and a structured metallic electroless plating structure formed on at least one sidewall of the stack.

According to another exemplary embodiment of the sixth aspect of the disclosure, a method of manufacturing a component carrier is provided, wherein the method comprises providing a stack comprising at least one electrically conductive layer structure and at least one electrically insulating layer structure, forming a recess at least partially in the stack, forming a structured poorly adhesive structure on at least one sidewall of the stack, and forming a structured metallic electroless plating structure on said at least one sidewall of the stack selectively apart from the structured poorly adhesive structure.

According to still another exemplary embodiment of the disclosure, component carriers having the above-mentioned features are used for a high-frequency application, in particular for conducting a radio frequency (RF) signal, in particular a radio frequency signal with a frequency above 1 GHz.

### Overview of Embodiments

In the context of the present application, the term “component carrier” may particularly denote any support structure which is capable of accommodating one or more components thereon and/or therein for providing mechanical support and/or electrical connectivity. In other words, a component carrier may be configured as a mechanical and/or electronic carrier for components. In particular, a component carrier may be one of a printed circuit board, an organic interposer, and an IC (integrated circuit) substrate. A component carrier may also be a hybrid board combining different ones of the above-mentioned types of component carriers.

In the context of the present application, the term “stack” may particularly denote an arrangement of multiple planar layer structures which are mounted in parallel on top of one another.

In the context of the present application, the term “layer structure” may particularly denote a continuous layer, a patterned layer or a plurality of non-consecutive islands within a common plane.

In the context of the present application, the terms “width and length of the recess” may particularly denote two orthogonal dimensions of the recess within a horizontal plane of the component carrier, i.e. a plane parallel to the main surfaces of the plate-shaped component carrier. Correspondingly, the height of the recess may extend vertically and perpendicular to the width and the length directions and may be oriented perpendicular to the main surfaces of the component carrier. A variation of the width of the recess along the length of the recess by not more than 75 μm means that a difference between a maximum value and a minimum value of the width along the length of the recess does not exceed 75 μm. Reference is also made to FIG. 20. For example, the width dimension may be smaller than the length dimension. In the context of the present application, the term “waveguide” may particularly denote a structure that guides waves, such as electromagnetic waves or sound, with reduced loss of energy by restricting the transmission of energy to a limited number of directions, in particular, to one direction. Without the physical constraint of a waveguide, wave amplitudes decrease more quickly as they expand into the three-dimensional space. For instance, a waveguide may be a hollow conductive recess in a layer stack of a component carrier which may be used to carry high-frequency radio waves. For instance, a cross-section of a metallized recess functioning as waveguide may be rectangular or circular. For instance, a signal may be coupled with a waveguide using a stripline, i.e. a transverse electromagnetic transmission line such as a planar transmission line. In particular, a signal may be coupled between waveguide and stripline at a waveguide-to-stripline transition.

In the context of the present application, the term “ridge” may particularly denote an elevation or protrusion to be attached to a stack of a component carrier and having a central through hole for exposing a surface portion of the stack in which a recess is to be created. Such a ridge, which may for instance be a dielectric material which may be applied easily by printing or dispensing may also serve for protecting underneath stack material during processing and may further function as a guide structure along which part of an electric connection between a waveguide and a connected wiring structure may extend. For instance, a ridge may be a ring or a layer with through hole.

In the context of the present application, the term “poorly adhesive structure” may particularly denote a physical structure made of material which has the property of not or only extremely weakly adhering to stack material of a component carrier such as a printed circuit board. In particular, such a stack material may comprise copper and resin (in particular epoxy resin), optionally comprising reinforcing particles such as glass fiber. The poorly adhesive structure may be embodied as a release layer at which layer structures of the stack above and beneath the release layer may be separated without the need of overcoming adhesive forces. For instance, such a poorly adhesive structure may be made of Teflon®, a waxy material or a suitable varnish. Teflon® is a registered mark of The Chemours Company FC LLC of Wilmington, Delaware, U.S.A. Examples for poorly adhesive materials which can be implemented according to exemplary embodiments of the disclosure are disclosed in WO 2015/113088 A1 (which is incorporated by reference in its entirety in the disclosure of the present application).

In the context of the present application, the term “electroless plating structure” may particularly denote a metallic structure formed by chemical processes that create metal coatings on underlying material (which may also be non-metallic) without electricity, in particular by an autocatalytic chemical reduction of metal cations in a liquid bath. Electroless plating is contrasted with electroplating processes, such as galvanization, where the reduction and deposition of a metal is achieved by an externally generated electric current. Electroless plating may also be denoted as chemical plating or autocatalytic plating. For instance, chemical copper may be applied by electroless plating.

In the context of the present application, the term “high-frequency application” may particularly denote a task fulfilled by the component carrier or to which the component carrier contributes, wherein the task may relate to the handling of a radio-frequency signal. Such a radio or high-frequency signal may be an electric or electromagnetic signal propagating along a wiring structure of the component carrier in a range of frequencies used for communications or other signals. In particular, a radio-frequency (RF) signal may for example have a frequency in the range between 3 kHz and 300 GHz.

According to an exemplary embodiment of the first aspect of the disclosure, a component carrier with integrated waveguide formed based on a recess is provided, wherein a plurality (i.e. at least two) of edges (in particular 12) of the recess are constituted by metallic material (see for instance FIG. 8, FIG. 12, or FIG. 22). Descriptively speaking, such metallized edges may form a metallic cage or fence delimiting the recess and forcing a radiofrequency signal such as a microwave to remain inside of the waveguide rather than propagating in an undefined way into the stack. Thereby, signal losses may be strongly suppressed and the signal quality as well as the high-frequency performance of the component carrier may be significantly improved.

According to an exemplary embodiment of the second aspect of the disclosure, a component carrier with integrated waveguide formed based on a recess with downwardly extending interior sidewalls in a stack of the component carrier is provided, wherein a width (as a first horizontal dimension) of the recess varies (in particular what concerns a difference between a maximum value and a minimum value of the width) along a length (as a second horizontal dimension perpendicular to the first horizontal dimension) of the recess by not more than 75 μm. Advantageously but not necessarily, such a small width tolerance may be promoted by sidewalls delimiting the recess which may have a smooth surface with a roughness Rz of 75 μm or less. In terms of the corresponding manufacturing process, such a downwardly extending sidewall with excellent width tolerance (and in particular smoothness) may be created in particular by embedding a poorly adhesive structure in the stack and by forming a circumferential trench in the stack extending downwardly at least up to the poorly adhesive structure. This allows separating a material piece delimited by the circumferential trench as well as by the poorly adhesive structure for forming the recess. By this manufacturing architecture, the trench may be formed (preferably by a cutting laser beam) in a single continuous process and therefore with high accuracy and high surface quality. Such a sidewall resulting in an extremely small width variation (and preferably with very small roughness Rz) is also an excellent basis for depositing an electrically conductive coating thereon which, in combination with the recess, may function as a waveguide with extremely low loss. Descriptively speaking, high-frequency signals travel within a waveguide having precisely defined dimensions and substantially only in a very thin skin-like surface film of the electrically conductive coating, which is also denoted as skin effect. When the width tolerance is small (and preferably the surface quality of the electrically conductive coating on the sidewall is high), the high-frequency losses occurring under consideration of the skin effect may be very low. A corresponding component carrier is thus highly appropriate for high-frequency applications.

According to an exemplary embodiment of the third aspect of the disclosure, a component carrier with integrated waveguide formed based on a recess in a stack of the component carrier is provided, wherein an electrically conductive coating on sidewalls of the recess is electrically coupled in a highly reliable way via the ridge with a horizontal wiring structure of the stack. Descriptively speaking, the ridge may function as an elevation on the stack along which electrically conductive material may be guided for accomplishing a reliable and continuous electric connection between the wiring structure (in particular one or more electrically conductive traces) and the electrically conductive material in the recess. Hence, a transition between the waveguide (in form of a recess lined with electrically conductive coating) and the wiring structure (in particular functioning as stripline) may be established with excellent electrical properties. Therefore, a high-frequency signal may be reliably coupled between waveguide and stripline with low loss. Signal transmission as promoted by the ridge may significantly improve the high-frequency performance of the component carrier.

According to an exemplary embodiment of the fourth aspect of the disclosure, a poorly adhesive structure (such as a release layer) is provided as part of a stack of a component carrier to be manufactured, wherein coverage of at least part of a layer structure of the stack by the poorly adhesive structure may enable the execution of a highly selective electroless deposition of metallic material exclusively on a precisely definable sub-portion of the surface of the stack, but not on another sub-portion of the surface of the stack covered with the poorly adhesive structure. More precisely, the poorly adhesive structure may be inert for electroless plating and may thus function as a protection structure for a surface portion of the stack covered by the poorly adhesive structure, since it has been surprisingly found that electroless deposition of metallic material does not work (or does not work to a noteworthy extent) on poorly adhesive material such as release layer material. Hence, chemical metal may be deposited on the stack but will only remain attached on surface portions of the stack which are not protected by the poorly adhesive structure. Thereafter, the poorly adhesive structure may or may not be removed, and functions in both alternatives for precisely defining regions of chemical metal coverage. Advantageously, a patterned electrically conductive layer structure may be protected by the poorly adhesive structure for preventing undesired bridging of different pattern portions of the electrically conductive layer structure by the electroless plated metal. Further advantageously, the poorly adhesive structure may be synergistically used for two purposes, i.e. selective electroless deposition and additionally a release layer function contributing to defining a stack portion to be isolated from the rest of the stack by the release layer in combination with a circumferential cut.

According to an exemplary embodiment of the fifth aspect of the disclosure, a component carrier is provided which has a waveguide-type recess in a layer stack, said recess being laterally delimited by an electrically conductive coating on sidewalls of the stack and being curved outwardly on an upper end of the sidewalls. By curving an uppermost portion of the electrically conductive coating outwardly (which may be achieved by forming the recess by laser cutting and appropriately setting the process parameters), vertical pressing forces acting on the stack when attaching additional layer structures on a top side for closing the recess may be damped by the smooth curvature of the metallic coating. Descriptively speaking, the outwardly curved metallic coating in an upper lateral section of the recess may be capable of accomplishing stress buffering upon lamination. At the same time, the described geometry has turned out to keep high-frequency wave propagation in the waveguide substantially undisturbed.

According to an exemplary embodiment of the sixth aspect of the disclosure, a component carrier is provided which has a recess in a layer stack, wherein a partial deposition of copper in embedded cavities may occur also on vertical sidewalls thereof. More specifically, any or each sidewall can be structured with a process flow using a poorly adhesive structure (in particular a release layer, preferably having hydrophobic properties) as protective coating. Hence, not only a top and/or bottom wall can be structured, but additionally or alternatively a sidewall. Optionally but not necessarily, such an embedded cavity may be configured as a waveguide, but may also be used for another purpose or application. In a nutshell, such a component carrier may have partially structured metal on sidewalls of a cavity or recess, which may be defined by a patterned poorly adhesive structure on which plated metal (such as plated copper) does not adhere. In particular, the structured poorly adhesive structure and the structured metallic electroless plating structure may be inverse structures.

In the following, further exemplary embodiments of the component carriers and the methods will be explained.

In an embodiment, all (in particular four) vertical edges delimiting the recess are formed by electrically conductive material of the at least one electrically conductive layer structure and/or of the electrically conductive coating. Specifically metallized vertical edges may have a strong advantageous impact on the suppression of signal loss of radiofrequency radiation propagating out of the cavity.

In an embodiment, all (in particular 12) edges delimiting the recess are formed by electrically conductive material of the at least one electrically conductive layer structure and/or of the electrically conductive coating. When all edges are metallized, signal loss out of the recess may be strongly suppressed and signal quality may be strongly improved.

In an embodiment, at least two sidewalls, in particular at least three sidewalls, more particularly all four sidewalls, of the recess are completely covered with electrically conductive material of the at least one electrically conductive layer structure and/or of the electrically conductive coating. Fully metallized sidewalls function as a highly efficient measure for forcing a microwave to remain inside of the waveguide.

In an embodiment, at least one of a top wall, a bottom wall, and at least one sidewall of the recess is or are partially or completely covered with electrically conductive material of the at least one electrically conductive layer structure and/or of the electrically conductive coating. Metallization of upper and/or lower main surfaces, partially or entirely, of the cavity may also contribute to the suppression of signal loss. Additionally or alternatively, such an electrically conductive material may be provided on any of the sidewalls.

In an embodiment, the recess is completely surrounded by electrically conductive material of the at least one electrically conductive layer structure and/or of the electrically conductive coating with the only exception of at least one opening for feeding a signal. Hence, one or more openings for signal transmission may be provided in the circumferential metal cage, preferably at the top and/or bottom wall. The one or more openings may be the only interruption of the metal cage surrounding the cavity. In other words, the metal cage may surround the cavity hermetically, with the only exception of the one or more openings for signal transmission (for example feed openings). Said one or more openings for signal transmission may be formed in a top wall and/or in a bottom wall of the metallic cage. In particular, sidewalls delimiting the cavity may be fully or partially covered by an electrically conductive medium such as copper. The mentioned one or more openings for signal transmissions may comprise at least one input opening and/or at least one output opening.

In an embodiment, at least one edge at an upper side and/or at a lower side of the recess comprises a metal-metal oxide-metal succession. When forming metal-metal interfaces, for instance by placing a metallic lid on a recessed stack with an at least partially metallic upper side, a metal oxide layer may be automatically maintained between two connected metallic structures. A metal oxide layer sandwiched between two metallic structures may have an advantageous impact on the adhesion of the component carrier. More specifically, the adhesion may be improved, as the surface tension changes from a copper-specific surface tension to a copper-oxide specific surface tension. Also, the roughness may be increased.

Preferably, the width of the recess varies (or deviates when comparing a maximum value with a minimum value of the width) along the length of the recess by not more than 20 μm, in particular by not more than 15 μm. With such small values of the width tolerance, excellent properties in terms of electromagnetic signal transmission via the waveguide may be achieved.

In an embodiment, the length of the recess varies along the width of the recess by not more than 75 μm, preferably by not more than 20 μm, and most preferably by not more than 15 μm. Hence, also the length tolerance may be small which may also have a positive impact on signal transmission quality and low losses.

In an embodiment, the stack has a sidewall, delimiting the recess, which has a roughness Rz in a range from 15 μm to 75 μm. Preferably, the sidewall has a roughness Rz of not more than 10 μm, in particular of not more than 7 μm, more particularly of not more than 5 μm. In the context of the present application, the term “roughness Rz” may particularly denote a measure for the roughness which can be determined when a reference length is sampled from a roughness curve in a direction of a mean line, and may denote the distance between the top profile peak line and the bottom profile valley line on this sampled portion as measured in the longitudinal direction of the roughness curve (for instance, Rz may be determined by averaging over five individual measuring paths). For example, the measurement or determination of roughness Rz may be carried out according to DIN EN ISO 4287:1984. As already mentioned above, with these very small roughness values, which can be achieved for instance by pulsed laser cutting using a picosecond laser source, an excellent transport of signals of very high frequencies may be ensured in view of the skin effect.

In an embodiment, at least part of the sidewall is covered with an electrically conductive coating. By covering the smooth sidewall delimiting the recess with an electrically conductive coating (which may be continuous and/or of uniform thickness), a highly efficient waveguide may be created.

In an embodiment, at least one of the at least one electrically conductive layer structure is exposed at at least part of the sidewall. Rather than coating preferably an entire sidewall delimiting a recess in the stack with an electrically conductive coating, it may also be possible to create the recess so that its sidewall is at least partially delimited by electrically conductive layer structures of the stack itself. Such electrically conductive layer structures may include horizontal metallic layers (for example copper foils) and/or vertical through connections (such as copper vias).

In an embodiment, at least one of the at least one electrically conductive layer structure defines a bottom (and in particular is exposed at a bottom) of the recess. Hence, an electric or electromagnetic signal may be coupled into the waveguide or out of the waveguide at the bottom side of the recess.

In an embodiment, the at least one of the at least one electrically conductive layer structure defining or being exposed at the bottom of the recess is a patterned layer. More specifically, the metallic layer may be patterned for rendering it appropriate for coupling a signal from the patterned layer into the metallized recess or out of the metallized recess into the patterned layer. For instance, a stripline may be defined as a transition to the recess-type waveguide by the patterning of the metallic layer.

In an embodiment, an uppermost one of the at least one electrically conductive layer structure is a patterned layer. Thus, a signal may be coupled into the waveguide or out of the waveguide at the top side of the recess. Said metallic layer may be structured for matching it with needs in relation to the coupling of a signal from the patterned top layer into the metallized recess or out of the metallized recess into the top side patterned layer. Hence, also the uppermost patterned electrically conductive layer structure may be adapted as a stripline functioning as a transition to the recess-type waveguide.

In an embodiment, the component carrier comprises a frequency filter structure in the recess and/or at material of the stack delimiting the recess. By frequency filtering a signal at the waveguide, signal quality may be further increased, and noise and unrelated signals may be suppressed. For instance, such a frequency filter may be a high-pass, a low-pass or a band-pass filter integrated in the stack of the component carrier structure. In particular, the electrically conductive layer structures of the stack may be adjusted for providing such a frequency filter function.

In an embodiment, the frequency filter structure is formed by a plurality of webs or ribs of at least one of the at least one electrically insulating layer structure at at least part of the sidewall, and by an electrically conductive structure formed on and/or between the webs. For instance, a corresponding embodiment is shown in FIG. 17. This approach is space-saving and highly precise. Alternatively, it is also possible to integrate a frequency filter structure as a freestanding body in the recess.

In an embodiment, a horizontal surface of at least one of the at least one electrically conductive layer structure has a roughness Rz of not more than 1 μm, in particular of not more than 0.5 μm, more particularly of not more than 0.2 μm. In addition to a high surface quality of the sidewall surfaces of the recess, it has turned out that providing at least part of the surface of at least one electrically conductive wiring structure with the mentioned high smoothness or low roughness properties may allow to obtain remarkably advantageous properties in terms of PIM behavior. The undesired phenomenon of passive intermodulation (PIM) may deteriorate high-frequency signal transmission over a component carrier. Passive intermodulation can substantially degrade the overall performance of mobile communication systems, etc. With the mentioned low roughness of the electrically conductive layer structure(s), advantageous high-frequency properties may be achieved.

In an embodiment, the component carrier comprises an antenna structure in the recess and/or at material of the stack delimiting the recess. In the context of the present application, the term “antenna structure” may particularly denote an electrically conductive structure shaped, dimensioned and configured to be capable of receiving and/or transmitting electromagnetic radiation signals corresponding to electric or electromagnetic signals which may be conducted along the electrically conductive wiring structures of the component carrier. By such an antenna structure integrated in the stack or formed at or in the recess, a signal may be coupled into the recess-based waveguide or out of the recess-based waveguide.

In an embodiment, the antenna structure is a free-standing structure in the recess, is circumferentially spaced with respect to surrounding material of the stack by a gap, and comprises part of at least one of the at least one electrically conductive layer structure. Such an embodiment is shown for instance in FIG. 8 and allows to provide an antenna structure with high precision and in a compact way. Alternatively, an antenna structure may be integrated in a sidewall of the stack adjacent to the recess (compare for instance FIG. 16).

In an embodiment, the sidewall is circumferentially closed and extends continuously vertical, in particular without layer displacement artifacts. Thus, the sidewall may be free of mechanical obstructions or structural inconsistencies. This may further promote a proper signal propagation with low losses.

In an embodiment, the sidewall is circumferentially closed and has at least one step. Descriptively speaking, such steps may be helpful for a proper transition of signals in a guided fashion. By providing one or multiple steps in the cavity or recess, the electromagnetic properties and signal transmission properties of the waveguide may be fine-tuned. The macroscopic steps may be much larger than (in particular at least tenfold of) dimensions corresponding to the surface roughness of the sidewalls so that the propagation of signals is not disturbed in view of the skin effect. Additionally or alternatively to the provision of steps, it may also be possible to provide ramps or other bottom structures in the recess for adjusting, guiding, or refining signal transmission.

In an embodiment, the method comprises forming a poorly adhesive structure (for instance a non-stick structure or anti-stick structure) in an interior of the stack, forming a circumferentially closed trench in the stack extending up to the poorly adhesive structure, and removing a material piece, delimited by the trench and the poorly adhesive structure, from the stack. Thus, formation of the recess used as a basis for constructing a waveguide may be carried out by embedding a release layer in the stack and cutting out the material piece, for instance by a pulsed laser beam. The non-sticky properties of the poorly adhesive structure with respect to the surrounding stack material may then be used for creating the recess by simply taking out the isolated material piece from the stack which is releasable at the bottom side thanks to the poorly adhesive structure.

In an embodiment, the method comprises forming a further poorly adhesive structure in an interior of the stack, forming a further circumferentially closed trench in the stack extending up to the further poorly adhesive structure, the further circumferentially closed trench having another diameter and/or depth than and/or being laterally displaced with respect to the circumferentially closed trench, and removing a further material piece, delimited by the further trench and the further poorly adhesive structure, from the stack. The hollow blind holes created based on the poorly adhesive structure in combination with the trench and based on the further poorly adhesive structure in combination with the further trench, respectively, may partially overlap in a horizontal plane and/or in a vertical direction. Thus, the aforementioned process of removing a material piece from the stack may be repeated once or several times in the same stack but at different stack positions and/or over different spatial ranges of the stack. By removing multiple material pieces from the stack in the described way, even more complex recess shapes may be created. For example, recesses with one or more macroscopic steps may be defined in this way. It is also possible to create with this repeated isolation of material pieces from the stack recesses in which a part of the sidewall is free of a metal coating.

In an embodiment, the method comprises forming the trench by laser cutting, in particular using a picosecond laser or a femtosecond laser. Advantageously, laser cutting can create extremely smooth surfaces. Preferably, laser cutting can be accomplished with a pulsed laser beam for further refining the surface quality. In particular, laser cutting can be accomplished with a pulsed laser which promotes low roughness sidewalls. It has turned out as most advantageous to implement a picosecond laser (or even a femtosecond laser), in particular to suppress undesired carbonization at portions of the sidewalls. Descriptively speaking, carbonization may describe the phenomenon of accumulation of carbon black at a laser-burnt surface of the component carrier which may result from incomplete oxidation of carbon during laser cutting. With a picosecond pulsed laser, this phenomenon can be strongly suppressed. This may further improve the signal transmission quality of the component carrier with integrated waveguide or stripline-waveguide-transition.

In an embodiment, the method comprises forming a laser stop structure in the stack adjacent to (in particular directly beneath) the poorly adhesive structure. A laser stop structure can be denoted as a structure embedded in the stack and being configured for stopping a laser beam cutting into the stack at a predefined position or at least strongly decelerating the laser beam when the latter reaches the laser stop structure. In particular, a sufficiently robust copper structure may function as laser stop structure. The laser stop structure may be arranged directly adjacent to the poorly adhesive structure so that the laser cutting process stops when the poorly adhesive structure has been reached. By taking this measure, the accuracy of forming the recess may be improved.

In an embodiment, the component carrier comprises an electrically conductive lining on at least part of the ridge and electrically coupling the waveguide with the wiring structure. More specifically, a direct electric coupling path may be established from a metallized sidewall of the recess, along the electrically conductive lining (which may be for example integrally formed with the metallization of the sidewall) covering the ridge up to a wiring structure of the electrically conductive layer structure. Optionally, an electrically conductive adhesive (such as copper paste) may be applied between ridge and wiring structure for further improving the electric reliability of the connection.

In an embodiment, the electrically conductive lining circumferentially surrounds the ridge. This establishes a particularly low ohmic connection promoting low loss signal transmission with high reliability.

In an embodiment, the ridge is a ring with a central through hole aligned with the recess. Such a ridge may be easily attached to the stack, for instance by printing, dispensing or by a pick and place process. As an alternative, the elevation or ridge can also be formed by a layer (for instance a prepreg layer) with a through hole.

In a preferred embodiment, the ridge is made of an electrically insulating material. The electric coupling function of the ridge may then be established by a coating of the ridge with metallic material.

Alternatively, the ridge can be made entirely out of an electrically conductive material such as copper.

In an embodiment, the wiring structure is located on top of the ridge. In particular, the wiring structure may be the uppermost of the at least one electrically conductive layer structure. Thus, an electric signal may be coupled into the component carrier very close to an exterior main surface and therefore with short signal path.

In an embodiment, the component carrier comprises an at least partially dielectric layer having a central through hole accommodating the ridge and having substantially the same height as the ridge plus electrically conductive material on the ridge. After the ridge or elevation is attached to a planar main surface of the stack, it protrudes vertically beyond the stack which renders subsequent layer build-up by lamination difficult. In order to planarize the upper main surface after having attached the ridge, an additional dielectric layer with a cut-out corresponding to the lateral ridge dimensions may be imposed on the ridge and onto an exposed surface of the stack. Thereby, a substantially planar surface is obtained when the thickness of the dielectric layer corresponds to the thickness of the ridge plus a thickness of electrically conductive material applied on top of the ridge. Thereafter, the processed arrangement is properly fit for a subsequent layer build-up, by which for instance at least one further electrically conductive layer structure and at least one further electrically insulating layer structure may be attached (for example laminated) to the top side for closing the recess.

In an embodiment, the wiring structure comprises a feedline structure for coupling a signal between the wiring structure and the waveguide. Thereby, an electric transition between waveguide and stack metal may be accomplished.

In an embodiment, the method comprises applying an electrically conductive adhesive, in particular an electrically conductive paste, on at least part of the ridge for electrically coupling the waveguide with the wiring structure. For instance, copper paste or silver paste may be used for this purpose. Such an electrically conductive paste may be cured and may then establish a permanent electric connection between waveguide and a stripline or feedline.

In an embodiment, the component carrier comprises a recess being at least partially formed in the stack, wherein the poorly adhesive structure covers a bottom and/or at least one sidewall of the recess, and wherein the metallic electroless plating structure is formed on at least part of the stack delimiting a sidewall of the recess. Such a configuration may be manufactured by embedding the poorly adhesive structure in the stack and using it as release layer for removing a circumferentially separated material piece from the rest of the stack. After that, the poorly adhesive structure on the bottom of the recess may be used as a protection structure for preventing an underlying layer from being metallized during a metallization of the sidewall of the recess. The poorly adhesive structure may be inert to an electroless plating process, i.e. will not be covered by chemical metal created during such a process. The described arrangement is thus a fingerprint of two highly advantageous functions of the poorly adhesive structure.

In an embodiment, at least one of the at least one electrically conductive layer structure comprises a patterned metal layer at the bottom of the recess under the poorly adhesive structure. In particular, it may be highly advantageous to cover such a patterned metal layer at or on the bottom of the recess by a poorly adhesive structure such as a release layer during selectively depositing electroless metal on other surface portions apart from the poorly adhesive structure. Consequently, the patterned metal layer can be reliably prevented from being unintentionally covered with metal during a chemical metallization (in particular of an interior sidewall of a recess in the stack), which might unintentionally couple portions of the patterned metal layer separated by the patterning.

In an embodiment, the method comprises removing at least part of the poorly adhesive structure after forming the electroless plated metallic structure. For instance, this can be done by stripping, dissolving, etching or evaporation. Any undesired impact of the poorly adhesive structure in the readily manufactured component carrier may thus be prevented. Alternatively, the poorly adhesive structure may remain part of the component carrier (for instance when made of a low-k material, the poorly adhesive structure does not significantly contribute to signal losses during high frequency applications).

In an embodiment, a beak-shaped extension of the recess is formed between the electrically conductive coating and one of the at least one electrically conductive layer structure at the upper end of the sidewalls. Such tiny beak-shaped recesses may enable a fine-tuning of the waveguide properties (for instance in terms of frequency behaviour, limitation of losses, etc.). Simultaneously, beak-shaped recess extensions may allow dampening and balancing mechanical forces which may occur during pressing additional layer structures on top of the recess and surrounding stack material.

In an embodiment, the recess is delimited at a lower end of the sidewalls by a tilted metallic section formed in an interface region between the electrically conductive coating and one of the at least one electrically conductive layer structure. Such slightly tilted metallic sections at bottom corners of the recess may also take up and redirect compressive vertical forces during pressing or laminating additional layer structures on top of the stack, and may lead to a more balanced force distribution along vertical and horizontal directions.

In an embodiment, the electrically conductive coating tapers downwardly in a central part of the sidewalls. Hence, slightly slanted or tilted sidewalls may be present in a central lateral portion of the recess. Preferably, the orientation of the slanted central portion of the sidewall may deviate from a vertical orientation by not more than 10%. This may further promote bending properties of the waveguide structure during build-up of further layers and may thereby protect the waveguide structure from damage during the manufacturing process.

In an embodiment, over a horizontal range between two opposing intersections between the electrically conductive coating and one of the at least one electrically conductive layer structure at the bottom of the recess, a height of the recess varies by not more than 20%, in particular by not more than 10%. It is preferred that in a vertical direction thickness tolerances are not excessive. This has advantageous properties on the high frequency behaviour of the waveguide. RF losses may thus be efficiently suppressed.

In an embodiment, a locally thickened metallic region is formed as an intersection between the electrically conductive coating and one of the at least one electrically conductive layer structure at the bottom of the recess. Such a local metallic thickening in bottom corner regions of the recess may function as mechanically robust reinforcing structure capable of taking up forces during pressing additional layer structures on top of the recess.

In an embodiment, the electrically conductive coating is substantially S-shaped at at least one of the sidewalls. Descriptively speaking, such a substantial S-shape of the metallic sidewall coating may function as a mechanical spring damping pressing forces during lamination.

In an embodiment, the component carrier is used for high-frequency applications above 1 GHz, in particular about 28 GHz. In particular for such high frequencies, signal transmission is particularly sensitive to surface roughness caused artefacts in view of the skin effect. The high PIM performance of component carriers according to exemplary embodiments of the disclosure allows low loss signal transmission even with such high-frequency values.

In an embodiment, the component carrier comprises a stack of at least one electrically insulating layer structure and at least one electrically conductive layer structure. For example, the component carrier may be a laminate of the mentioned electrically insulating layer structure(s) and electrically conductive layer structure(s), in particular formed by applying mechanical pressure and/or thermal energy. The mentioned stack may provide a plate-shaped component carrier capable of providing a large mounting surface for further components and being nevertheless very thin and compact.

In an embodiment, the component carrier comprises a stack of at least one electrically insulating layer structure and at least one electrically conductive layer structure. For example, the component carrier may be a laminate of the mentioned electrically insulating layer structure(s) and electrically conductive layer structure(s), in particular formed by applying mechanical pressure and/or thermal energy. The mentioned stack may provide a plate-shaped component carrier capable of providing a large mounting surface for further components and being nevertheless very thin and compact.

In an embodiment, the component carrier is shaped as a plate. This contributes to the compact design, wherein the component carrier nevertheless provides a large basis for mounting components thereon. Furthermore, in particular a naked die as example for an embedded electronic component, can be conveniently embedded, thanks to its small thickness, into a thin plate such as a printed circuit board.

In an embodiment, the component carrier is configured as one of the group consisting of a printed circuit board, a substrate (in particular an IC substrate), and an interposer.

In the context of the present application, the term “printed circuit board” (PCB) may particularly denote a plate-shaped component carrier which is formed by laminating several electrically conductive layer structures with several electrically insulating layer structures, for instance by applying pressure and/or by the supply of thermal energy. As preferred materials for PCB technology, the electrically conductive layer structures are made of copper, whereas the electrically insulating layer structures may comprise resin and/or glass fibers, so-called prepreg or FR4 material. The various electrically conductive layer structures may be connected to one another in a desired way by forming holes through the laminate, for instance by laser drilling or mechanical drilling, and by partially or fully filling them with electrically conductive material (in particular copper), thereby forming vias or any other through-hole connections. The filled hole either connects the whole stack, (through-hole connections extending through several layers or the entire stack), or the filled hole connects at least two electrically conductive layers, called via. Similarly, optical interconnections can be formed through individual layers of the stack in order to receive an electro-optical circuit board (EOCB). Apart from one or more components which may be embedded in a printed circuit board, a printed circuit board is usually configured for accommodating one or more components on one or both opposing surfaces of the plate-shaped printed circuit board. They may be connected to the respective main surface by soldering. A dielectric part of a PCB may be composed of resin with reinforcing fibers (such as glass fibers).

In the context of the present application, the term “substrate” may particularly denote a small component carrier. A substrate may be a, in relation to a PCB, comparably small component carrier onto which one or more components may be mounted and that may act as a connection medium between one or more chip(s) and a further PCB. For instance, a substrate may have substantially the same size as a component (in particular an electronic component) to be mounted thereon (for instance in case of a Chip Scale Package (CSP)). More specifically, a substrate can be understood as a carrier for electrical connections or electrical networks as well as component carrier comparable to a printed circuit board (PCB), however with a considerably higher density of laterally and/or vertically arranged connections. Lateral connections are for example conductive paths, whereas vertical connections may be for example drill holes. These lateral and/or vertical connections are arranged within the substrate and can be used to provide electrical, thermal and/or mechanical connections of housed components or unhoused components (such as bare dies), particularly of IC chips, with a printed circuit board or intermediate printed circuit board. Thus, the term “substrate” also includes “IC substrates”. A dielectric part of a substrate may be composed of resin with reinforcing particles (such as reinforcing spheres, in particular glass spheres).

The substrate or interposer may comprise or consist of at least a layer of glass, silicon (Si) and/or a photoimageable or dry-etchable organic material like epoxy-based build-up material (such as epoxy-based build-up film) or polymer compounds (which may or may not include photo- and/or thermosensitive molecules) like polyimide or polybenzoxazole.

In an embodiment, the at least one electrically insulating layer structure comprises at least one of the group consisting of a resin or a polymer, such as epoxy resin, cyanate ester resin, benzocyclobutene resin, bismaleimide-triazine resin, polyphenylene derivate (e.g. based on polyphenylenether, PPE), polyimide (PI), polyamide (PA), liquid crystal polymer (LCP), polytetrafluoroethylene (PTFE) and/or a combination thereof. Rein-forcing structures such as webs, fibers, spheres or other kinds of filler particles, for example made of glass (multilayer glass) in order to form a composite, could be used as well. A semi-cured resin in combination with a reinforcing agent, e.g. fibers impregnated with the above-mentioned resins is called prepreg. These prepregs are often named after their properties e.g. FR4 or FR5, which describe their flame retardant properties. Although prepreg particularly FR4 are usually preferred for rigid PCBs, other materials, in particular epoxy-based build-up materials (such as build-up films) or photoimageable dielectric materials, may be used as well. For high frequency applications, high-frequency materials such as polytetrafluoroethylene, liquid crystal polymer and/or cyanate ester resins, may be preferred. Besides these polymers, low temperature cofired ceramics (LTCC) or other low, very low or ultra-low DK materials may be applied in the component carrier as electrically insulating structures.

In an embodiment, the at least one electrically conductive layer structure comprises at least one of the group consisting of copper, aluminum, nickel, silver, gold, palladium, tungsten and magnesium. Although copper is usually preferred, other materials or coated versions thereof are possible as well, in particular coated with supra-conductive material or conductive polymers, such as graphene or poly(3,4-ethylenedioxythiophene) (PEDOT), respectively.

The at least one component can be selected from a group consisting of an electrically non-conductive inlay, an electrically conductive inlay (such as a metal inlay, preferably comprising copper or aluminum), a heat transfer unit (for example a heat pipe), a light guiding element (for example an optical waveguide or a light conductor connection), an electronic component, or combinations thereof. An inlay can be for instance a metal block, with or without an insulating material coating (IMS-inlay), which could be either embedded or surface mounted for the purpose of facilitating heat dissipation. Suitable materials are defined according to their thermal conductivity, which should be at least 2 W/mK. Such materials are often based, but not limited to metals, metal-oxides and/or ceramics as for instance copper, aluminum oxide (Al₂O₃) or aluminum nitride (AlN). In order to increase the heat exchange capacity, other geometries with increased surface area are frequently used as well. Furthermore, a component can be an active electronic component (having at least one p-n-junction implemented), a passive electronic component such as a resistor, an inductance, or capacitor, an electronic chip, a storage device (for instance a DRAM or another data memory), a filter, an integrated circuit (such as field-programmable gate array (FPGA), programmable array logic (PAL), generic array logic (GAL) and complex programmable logic devices (CPLDs)), a signal processing component, a power management component (such as a field-effect transistor (FET), metal-oxide-semiconductor field-effect transistor (MOSFET), complementary metal-oxide-semiconductor (CMOS), junction field-effect transistor (JFET), or insulated-gate field-effect transistor (IGFET), all based on semiconductor materials such as silicon carbide (SiC), gallium arsenide (GaAs), gallium nitride (GaN), gallium oxide (Ga₂O₃), indium gallium arsenide (InGaAs) and/or any other suitable inorganic compound), an optoelectronic interface element, a light emitting diode, a photocoupler, a voltage converter (for example a DC/DC converter or an AC/DC converter), a cryptographic component, a transmitter and/or receiver, an electromechanical transducer, a sensor, an actuator, a microelectromechanical system (MEMS), a microprocessor, a capacitor, a resistor, an inductance, a battery, a switch, a camera, an antenna, a logic chip, and an energy harvesting unit. However, other components may be embedded in the component carrier. For example, a magnetic element can be used as a component. Such a magnetic element may be a permanent magnetic element (such as a ferromagnetic element, an antiferromagnetic element, a multiferroic element or a ferrimagnetic element, for instance a ferrite core) or may be a paramagnetic element. However, the component may also be an IC substrate, an interposer or a further component carrier, for example in a board-in-board configuration. The component may be surface mounted on the component carrier and/or may be embedded in an interior thereof. Moreover, also other components, in particular those which generate and emit electromagnetic radiation and/or are sensitive with regard to electro-magnetic radiation propagating from an environment, may be used as component.

In an embodiment, the component carrier is a laminate-type component carrier. In such an embodiment, the component carrier is a compound of multiple layer structures which are stacked and connected together by applying a pressing force and/or heat.

After processing interior layer structures of the component carrier, it is possible to cover (in particular by lamination) one or both opposing main surfaces of the processed layer structures symmetrically or asymmetrically with one or more further electrically insulating layer structures and/or electrically conductive layer structures. In other words, a build-up may be continued until a desired number of layers is obtained.

After having completed formation of a stack of electrically insulating layer structures and electrically conductive layer structures, it is possible to proceed with a surface treatment of the obtained layers structures or component carrier.

In particular, an electrically insulating solder resist may be applied to one or both opposing main surfaces of the layer stack or component carrier in terms of surface treatment. For instance, it is possible to form such a solder resist on an entire main surface and to subsequently pattern the layer of solder resist so as to expose one or more electrically conductive surface portions which shall be used for electrically coupling the component carrier to an electronic periphery. The surface portions of the component carrier remaining covered with solder resist may be efficiently protected against oxidation or corrosion, in particular surface portions containing copper.

It is also possible to apply a surface finish selectively to exposed electrically conductive surface portions of the component carrier in terms of surface treatment. Such a surface finish may be an electrically conductive cover material on exposed electrically conductive layer structures (such as pads, conductive tracks, etc., in particular comprising or consisting of copper) on a surface of a component carrier. If such exposed electrically conductive layer structures are left unprotected, then the exposed electrically conductive component carrier material (in particular copper) might oxidize, making the component carrier less reliable. A surface finish may then be formed for instance as an interface between a surface mounted component and the component carrier. The surface finish has the function to protect the exposed electrically conductive layer structures (in particular copper circuitry) and enable a joining process with one or more components, for instance by soldering. Examples for appropriate materials for a surface finish are Organic Solderability Preservative (OSP), Electroless Nickel Immersion Gold (ENIG), Electroless Nickel Immersion Palladium Immersion Gold (ENIPIG), gold (in particular hard gold), chemical tin, nickel-gold, nickel-palladium, etc.

The aspects defined above and further aspects of the disclosure are apparent from the examples of embodiment to be described hereinafter and are explained with reference to these examples of embodiment.

### BRIEF DESCRIPTION OF THE DRAWINGS

FIG. 1, FIG. 2, FIG. 3, FIG. 4, FIG. 5, FIG. 6, FIG. 7, and FIG. 8 illustrate cross-sectional views of structures obtained during carrying out a method of manufacturing a component carrier according to an exemplary embodiment of the disclosure, shown in FIG. 8.

FIG. 9 is a flow diagram of a method of manufacturing a component carrier according to an exemplary embodiment of the disclosure.

FIG. 10 is a flow diagram of a method of manufacturing a component carrier according to another exemplary embodiment of the disclosure.

FIG. 11 is a flow diagram of a method of manufacturing a component carrier according to still another exemplary embodiment of the disclosure.

FIG. 12 illustrates a component carrier according to an exemplary embodiment of the disclosure.

FIG. 13 illustrates a component carrier according to another exemplary embodiment of the disclosure.

FIG. 14 illustrates a component carrier according to still another exemplary embodiment of the disclosure.

FIG. 15 illustrates a component carrier according to yet another exemplary embodiment of the disclosure.

FIG. 16 illustrates a component carrier according to yet another exemplary embodiment of the disclosure.

FIG. 17 illustrates a component carrier according to yet another exemplary embodiment of the disclosure.

FIG. 18 illustrates a component carrier according to yet another exemplary embodiment of the disclosure.

FIG. 19 illustrates a component carrier according to yet another exemplary embodiment of the disclosure.

FIG. 20 illustrates dimensions of a waveguide-type recess of a component carrier according to an exemplary embodiment of the disclosure.

FIG. 21 illustrates a cross-sectional image of a manufactured component carrier with interior waveguide-type recess according to an exemplary embodiment of the disclosure.

FIG. 22 illustrates a cross-sectional view of a component carrier with interior waveguide-type recess according to an exemplary embodiment of the disclosure and corresponding to the image of FIG. 21.

### DETAILED DESCRIPTION OF ILLUSTRATED EMBODIMENTS

The illustrations in the drawings are schematically presented. In different drawings, similar or identical elements are provided with the same reference signs.

Before referring to the drawings, exemplary embodiments will be described in further detail, some basic considerations will be summarized based on which exemplary embodiments of the disclosure have been developed.

According to an exemplary embodiment of the disclosure, a compact component carrier with integrated low-loss waveguide or hollow conductor may be provided. In a structured hollow conductor according to an exemplary embodiment of the disclosure, a bottom-side copper layer is first structured, after which a non-sticky coating, which is not metallized in a subsequent metallization process, is printed on the structured layer. Hence, a release layer is applied to a structured copper layer. After a further build-up of the stack and a laser cutting process, a recess is obtained. Sidewalls of the recess or cavity may then be selectively coated with metal, while the release layer is inert against electroless metal deposition and is thus selectively protected from being metal coated, and can then be removed. A selective coating with chemical copper is thus carried out for structuring the hollow conductor. In particular, metallized sidewalls may be manufactured without metal edges in the sidewall. Consequently, signal losses may be avoided. In addition, signal losses may be suppressed by the construction of a ridge or elevation as well as by covering the ridge with a copper foil, which can be structured. Furthermore, the described manufacturing method may allow to produce component carriers with integrated waveguide function on an industrial scale and with high throughput.

According to an exemplary embodiment of the disclosure, a fully metallized hollow waveguide may be provided which may include a structured feeding line on a bottom or top wall. A corresponding manufacturing process may allow to produce a transition between a structured metallized microstrip and a hollow waveguide. Advantageously, no structural artifacts (which may occur conventionally due to a layer shift resulting from a connection of two stacks for forming a component carrier) occurs in the middle of the waveguide wall according to exemplary embodiments.

In particular, a structured bottom cavity for a waveguide with metallized walls may be provided allowing to create an electrically closed waveguide. Such a waveguide may be a fully metallized air-filled waveguide with signal feeding structure on bottom. An air-filled substrate integrated waveguide may advantageously allow to obtain a low loss. At high frequencies and in particular at frequencies above 28 GHz, radar signal transmission may be achieved with high bandwidth. The high performance and low losses of the component carrier with integrated waveguide may be achieved by creating a corresponding recess using an embedded release layer which, in combination with laser cutting, allows to create the recess with high surface quality. This may allow to manufacture a component carrier-integrated waveguide without structural artifacts in the metallized sidewall. A ridge or wall may be built below a top copper layer for improving reliability of the electric coupling between waveguide and feedline. Advantageously, sidewalls of a recess in the stack constituting a waveguide may be electrically connected to top and bottom. In particular, a feeding structure on the bottom of the waveguide may be protected during an electroless copper process by release layer ink or another non-sticky or poorly adhesive structure.

For manufacturing a recess in the component carrier for forming the waveguide, a high accuracy may be achieved by implementing a picosecond laser cutter allowing to obtain a high accuracy (for instance tolerances of ±15 μm or less).

Exemplary embodiments of the disclosure provide structured, metallized hollow conductors and a transition between a strand-conductor and a hollow conductor. Furthermore, manufacturing processes for the manufacture of structured, metallized hollow conductors and strip conductor-hollow conductor transitions are provided. In particular, a manufacture of metallized hollow waveguides including structured bottom or top walls are possible.

Advantages of exemplary embodiments are that no dielectric signal loss occurs in an air-filled waveguide according to an exemplary embodiment of the disclosure. Further advantageously, a high bandwidth may be achieved in particular for frequencies above 28 GHz. Furthermore, it may be possible to manufacture a component carrier with waveguides and integrated three-dimensional antenna structures, for instance arranged along a vertical axis. Advantageously, no special low Dk or low Df dielectric materials are needed which may reduce the manufacturing effort. Hence, high effort due to the use of low Dk materials with high glass transition temperature can be avoided. Moreover, reliable single material type stack-ups can be produced with low effort and may be used for instance for different radar performance. Moreover, a structured fully metallized air-filled waveguide with low signal loss and high bandwidth may be provided.

Exemplary applications of exemplary embodiments of the disclosure are in particular 5G, 6G, an infrastructure base station and small cells. Further possible applications are automotive radar, industrial sensors, and THz range sensors for example for medical applications. Furthermore, exemplary embodiments allow to provide high-frequency component carriers (in particular for frequencies above 30 GHz). Further applications are internet of things applications, optical waveguides, etc.

Exemplary embodiments of the disclosure relate to structured, metallized hollow conductors and transitions between a strand-conductor and a hollow conductor which are integrated in a multilayer printed circuit board. Furthermore, a manufacturing process for these integrated structured, metallized hollow conductors and transitions between strand conductor and hollow conductor is provided. The application of the structured hollow conductor and strip conductor-hollow conductor transitions can serve as a connection between at least one antenna and at least one chip (or any other component which may be embedded in the stack or surface mounted on the stack). Furthermore, the structured hollow guide may function as a fiber optic or sound guide, as a transition component of waveguide to strip conductor, as antennas as well as part of pressure, sound, or light sensors. Furthermore, the hollow conductors according to an embodiment of the disclosure can also be used for transporting liquids and gases.

Multi-layer printed circuit boards comprise a stack of electrically conductive copper layers and electrically insulating layers of dielectric and are equipped with electronic components in or on the layer sequence. Hollow conductors are waveguides and are used for the transmission of waves, especially electromagnetic waves, light waves or sound waves. A hollow conductor can also serve as a channel for liquids such as cooling fluids and gases. In order to be able to conduct electromagnetic waves or light in a hollow conductor, a transition between a strip conductor and a hollow conductor may be desired.

An advantage of hollow conductors covered with metal is that these hollow conductors have low signal transmission losses and energy losses compared to those waveguides that are filled with dielectric and/or have at least partially opened sidewalls. Due to the cut-off frequency, hollow conductors have a frequency-dependent defined width and height. The higher the frequency of the wave to be directed, the smaller the wavelength and thus also the geometry of the hollow conductor. For the manufacture of PCBs, hollow conductors and transitions between strip conductor and hollow conductor with small dimensions are particularly appropriate in the high GHz frequency range for being integrated into the printed circuit board.

For example, the dimensions of a hollow conductor for the Ka band of 26-40 GHz are 7.1 mm in width and 3.6 mm in height, for the W band of 75-100 GHz 2.5 mm in width and 1.3 mm in height. The dimensions of a hollow conductor for the G band of 140-220 GHz are 1.3 mm in width and 0.6 mm in height and for the Y band of 750-1100 GHz are 0.25 mm in width and 0.13 mm in height.

As the frequency range increases, so do the requirements for the accuracy of the manufacture of the hollow conductors and transitions between strip conductor and hollow conductor. Thus, in the frequency range above 30 GHz, manufacture of hollow conductors and strip conductor hollow conductor transitions should preferably have tolerances below 40 μm to avoid noise and signal loss.

An embodiment of the disclosure relates to structured, metallized hollow conductors and transitions between strip conductor and hollow conductor which are integrated in the printed circuit board. Furthermore, a corresponding manufacturing process for producing such a structured, metallized hollow conductor and transitions between strip conductor and hollow conductor may be provided. Copper structures at the bottom of the hollow conductor according to an embodiment of the disclosure may be covered with at least one poorly adhesive structure formed of, for example, a fluorocarbon compound. The poorly adhesive structure may be inert in a process of physically and/or chemically applying a conductive catalytic layer such as for example chemical copper. The copper layer under the copper cover layer is preferably provided with at least one ridge or elevation in the area of the hollow conductor which is stable in the chemical copper process. Furthermore, the hollow conductor in the area of the ridge may be cut out by at least one high-precision separation process such as for example a laser cutting process. The resulting edge of the ridge as well as the sidewalls may be selectively coated with copper in a structured hollow conductor according to an embodiment of the disclosure. However, a structured metal area at the bottom is not additionally metallized. Beyond this, the cavity is covered in the further structuring process and in a subsequent build up during which at least one prepreg layer with openings around the copper edges of the ridge may be applied. The top layers of the obtained component carrier may be formed by a structured copper layer and an electrically conductive material in the area of the metallic wall.

Before applying a poorly adhesive structure to protect the copper structures at the bottom of the hollow conductor according to an embodiment of the disclosure, the copper structures at the bottom of the hollow conductor can be protected by end surface processes, which may include but are not limited to processes such as chemical silver, tin, ENIG or OSP processes.

Before applying the top layer(s), the structured hollow conductor, which may have sidewalls of copper, may be subjected to further processes such as galvanic copper processing for applying further metal to the sidewalls, laser drilling processes, photo processes and etching processes for structuring a copper layer under the copper top layer. Furthermore, end surfaces may be treated by processes including chemical silver, tin, ENIG, ENIPIG, hard gold or OSP. The structuring of the top copper layer, which closes the hollow conductor on the top, can include further processes such as galvanic copper for further copper construction of the sidewalls, laser drilling processes, photo processes and etching processes for structuring a copper layer under the copper top layer, as well as end surface processes such as chemical silver, tin, ENIG, OSP or a fluorocarbon coating which includes PTFE, PVDF, etc.

The issue of layer offset in the middle of the hollow conductor wall can be solved by embodiments of the present disclosure surprisingly by the fact that the high-precision separation process (such as the laser cutting process) cuts through the applied ridge and at the same time also through the underlying layers of the circuit board up to the laser stop position. It has been surprisingly found that, after the high-precision separation process (such as a laser cutting process), a copper plating of the edge of the ridge occurs together with a copper plating of the sidewalls of the hollow conductor, while the poorly adhesive structure simultaneously protects a structured metal layer on the bottom of the hollow conductor from copper deposition. This makes it possible to produce hollow conductors with sidewalls which are completely coated with metal, without compromising on the patterned character of the bottom metal layer.

For example, the structured hollow conductors can be used for the connection between antenna and chip as well as for the manufacture of a transition between hollow conductor and strip conductor. Furthermore, the structured hollow conductors may be employed in the GHz or THz frequency range as well as for the conduction of light or sound waves. Hollow conductors according to exemplary embodiments may have a higher bandwidth and lower signal losses than conventional waveguides. Furthermore, in the manufacturing process for the structured metallized hollow conductors according to an embodiment of the disclosure, well-defined processes of printed circuit board manufacturing technology such as printing processes, laser cutting processes and chemical copper processes, photo and etching processes as well as end surface processes, may be used for enabling a mass manufacture of the integrated hollow conductors with high precision and deviations below 30 μm.

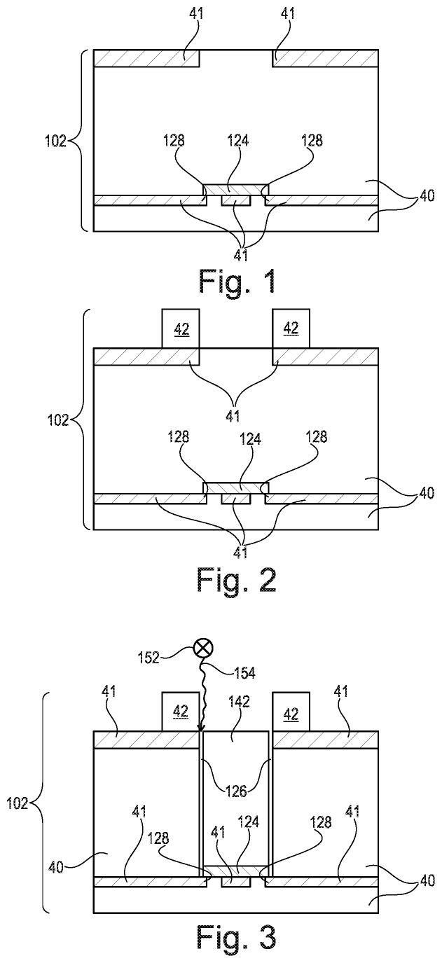

FIG. 1 to FIG. 8 illustrate cross-sectional views of structures obtained during carrying out a method of manufacturing a component carrier 100, such as a printed circuit board (PCB), according to an exemplary embodiment of the disclosure, shown in FIG. 8.

Referring to FIG. 1, a stack 102 is provided which comprises a plurality of electrically conductive layer structures 41 and a plurality of electrically insulating layer structures 40. The electrically insulating layer structures 40 may for instance comprise resin (such as epoxy resin), optionally comprising reinforcing particles such as glass fibers. For instance, the electrically insulating layer structures 40 may be made of prepreg. The electrically conductive layer structures 41 may comprise continuous and/or patterned copper layers and/or vertical through connections (not shown in FIG. 1) such as copper filled laser vias.

More specifically, in the embodiment shown in FIG. 1, a first electrically conductive layer structure 41 is a patterned metal layer embedded in the stack 102. A second electrically conductive layer structure 41 is another patterned metal layer located at a top surface of the stack 102.

Furthermore, a non-sticky or poorly adhesive structure 124 is embedded in an interior of the stack 102 and may be one of the electrically insulating layer structures 40. The poorly adhesive structure 124 may also be denoted as a release layer, because the adhesion of the poorly adhesive structure 124 with respect to neighboured layer structures 40, 41 in stack 102 is so poor that the stack 102 can be easily delaminated at the poorly adhesive structure 124 without the need of overcoming adhesion forces. For instance, the poorly adhesive structure 124 may be made of Teflon®. During the further manufacturing process, the poorly adhesive structure 124 can be advantageously used for two purposes: On the one hand, a recess 43 can be formed in the stack 102 by taking out a material piece 142 defined by a circumferential trench 126 and by the upper main surface of the poorly adhesive structure 124 thanks to its poor adhesion or release layer function (compare FIG. 3 and FIG. 4). On the other hand, the poorly adhesive structure 124 may remain on the patterned electrically conductive layer structure 41 directly beneath the poorly adhesive structure 124 for protecting said patterned electrically conductive layer structure 41 from an undesired metal coating during a chemical metal coating process described below in further detail (compare FIG. 5). Consequently, the patterned property of the underlying electrically conductive layer structure 41 may be maintained during said chemical metal coating process.

A further advantage of the described construction of stack 102 according to FIG. 1 is that the patterned electrically conductive layer structure 41 directly under the poorly adhesive structure 124 may synergistically function as a laser stop structure 128 in the stack 102 adjacent to the poorly adhesive structure 124, i.e. may stop a laser cutting process described below referring to FIG. 3. Alternatively, a separate laser stop structure may be provided in stack 102 in addition to the patterned electrically conductive layer structure 41 directly beneath the poorly adhesive structure 124.

Referring to FIG. 2, an elevation or ridge 42 is formed on or attached to the stack 102. The ridge 42 may be a ring of dielectric material, which may for instance be printed on top of the stack 102 and may be subsequently cured.

Referring to FIG. 3, a circumferentially closed trench 126 is formed in the stack 102 extending up to the embedded poorly adhesive structure 124. Formation of the trench 126 may be carried out by laser cutting using a laser source 152 emitting a laser beam 154 and being preferably movable relative to the stack 102. The laser stop structure 128 in the stack 102 may stop the laser cutting process at a pre-defined position, as mentioned above. Preferably, the laser beam 154 may be pulsed and may be most preferably a picosecond laser. It has turned out that this kind of cutting the stack 102 provides excellent spatial accuracy and hence formation of trench 126 with very low tolerances and without structural artefacts. Inner vertical sidewalls of the ridge 42 may be preferably aligned with the trench 126.

By formation of the circumferential trench 126 extending up to the poorly adhesive structure 124, a material piece 142 is separated from the rest of the stack 102. The material piece 142 is circumferentially delimited by the trench 126 and is delimited at its bottom side by the poorly adhesive structure 124 which does not adhere neither to the material piece 142 nor to the rest of the stack 102.

Referring to FIG. 4, said separated material piece 142 delimited by the trench 126 and the poorly adhesive structure 124 may then be removed from the stack 102 to thereby form blind hole-type recess 43 in the stack 102. Highly advantageously and also referring to FIG. 20, a width “W” of the recess 43 varies along a length “L” of the recess 43 by not more than 75 μm. According to a FIG. 4, the width “W” and the length “L” of the recess 43 are the dimensions of the recess 43 in the two horizontal dimensions extending in the paper plane and perpendicular to the paper plane, respectively, whereas a height “H” corresponds to a dimension of the recess 43 in a vertical direction according to FIG. 4 (compare FIG. 20). The mentioned design rule means that a difference between a maximum value and a minimum value of the width “W” along the length “L” does not exceed 75 μm. Furthermore, recess 43 may be characterized by exactly vertical sidewalls 110 being free of undesired micro-steps and having an extremely small surface roughness Rz of for example 15 μm. The small tolerance of the width “W” along the length “L” of the recess 43, to which also the continuously smooth circumferential surface of the sidewalls 110 of stack 102 defining the recess 43 contributes, is highly advantageous, since this promotes the quality of the electromagnetic wave formation in the waveguide. A metallic structure 140 (see FIG. 5) formed subsequently on the sidewalls 110 may also have very smooth sidewalls when formed on low-roughness interior sidewalls 110 of stack 102. Consequently, the readily manufactured component carrier 100 may have excellent high-frequency properties, since signal transport along such a smooth metallic structure 110 may be possible with very low losses. Descriptively speaking, according to the skin effect, a high-frequency signal will propagate substantially only in a thin surface skin of such a metallic structure 110 and will therefore highly benefit from the low roughness. The high-frequency signal can thus propagate with only lowest distortions around the hollow conductor or waveguide being presently produced.

As shown in FIG. 4 as well, the poorly adhesive structure 124 is exposed at a bottom 48 of the recess 43 by removing material piece 142 and remains on the beneath electrically conductive layer structure 41 as a protective structure to provide protection in a subsequent electroless plating process.

Referring to FIG. 5, a metallic structure 140 is formed by electroless plating selectively on a surface of the stack 102 apart from the poorly adhesive structure 124. For instance, chemical copper may be formed for lining the recess 43 and the ridge 42 with the metallic structure 140. Highly advantageously, no or substantially no electroless deposited metal adheres to the exposed surface of the poorly adhesive structure 124 due to its non-sticky properties. Further advantageously, the poorly adhesive structure 124 protectively covers the beneath patterned electrically conductive layer structure 41 and therefore prevents undesired deposition of metal thereon. This ensures that the structured or patterned character of said electrically conductive layer structure 41 is maintained. Since patterning said electrically conductive layer structure 41 at the bottom of the recess 43 would be at least extremely difficult, this protection is of utmost advantage.

As shown in FIG. 5, the metallic structure 140 may also be in direct physical contact with the lowermost structured electrically conductive layer structure 41 shown in FIG. 5.

If desired or required, the electroless deposited metallic material of metallic structure 140 may be further thickened by a subsequent optional galvanic metal deposition process by which additional metallic material may be galvanically deposited on exposed surfaces of the metallic structure 140. Consequently, the sidewalls 110 may be covered with an electrically conductive coating 44 of adjustable thickness.

By the formation of the metallic structure 140, said recess 43 is configured as waveguide or hollow conductor. As shown, the metallic structure 140 not only covers vertical sidewalls of the recess 43, but also exposed surface portions of the elevation or ridge 42 in form of electrically conductive lining 134.

Referring to FIG. 6, the poorly adhesive structure 124 can be removed after forming the metallic structure 140. For instance, this can be accomplished by etching, dissolving, or evaporating the poorly adhesive structure 124. Thereby, also the patterned electrically conductive layer structure 41 which had initially been protected by the poorly adhesive structure 124 can be exposed at bottom 48. This may make it possible to subsequently subject said electrically conductive layer structure 41 to a surface treatment process.

However, it is alternatively also possible that the poorly adhesive structure 124 remains at the bottom of recess 43 and forms part of the readily manufactured component carrier 100. Advantageously, appropriate materials for the poorly adhesive structure 124 as disclosed herein (for instance Teflon®) may be compatible with high-frequency applications and to not involve noteworthy losses.

Referring to FIG. 7, an optional electrically conductive adhesive 47 such as an electrically conductive paste (for instance comprising copper and/or silver) may be applied to the exposed top surface of the ridge 42 for electrically coupling the waveguide with a subsequently attached further electrically conductive layer structure 41 (see FIG. 8). The electrically conductive adhesive 47 may for instance be printed or dispensed on the top surface of ridge 42. This significantly improves the electric reliability of an electric coupling between the electrically conductive coating 44 delimiting the hollow recess 43 of the waveguide and the subsequently attached further electrically conductive layer structure 41 (see FIG. 8).

Hence, ridge 42—preferably but not necessarily in combination with the electrically conductive adhesive 47—may significantly improve the reliability of an electric connection between a stripline of the electrically conductive layer structures 41 and the waveguide with its electrically conductive coating 44 delimiting the hollow recess 43. Consequently, a highly reliable and low-loss transition between stripline and waveguide can be achieved with excellent electrical properties.

Moreover, a dielectric layer 136 (for example a prepreg layer) having a central through hole may be attached from above. Said through hole may accommodate the ridge 42. Dielectric layer 136 may have approximately the same height as the ridge 42 plus electrically conductive material (see reference signs 134 and 47) on the ridge 42. As a result, the obtained arrangement is planarized which is advantageous for the further build-up.

Referring to FIG. 8, the above-mentioned uppermost additional electrically conductive layer structure 41 and a continuous further electrically insulating layer structure 40 may be attached on top of said recess 43, on the electrically conductive adhesive 47 (or, when the latter is not present, on electrically conductive lining 134 being integrally connected with electrically conductive coating 44) and on annular dielectric layer 136. Said uppermost most electrically conductive layer structure 41 may also be patterned (in particular in its portion above recess 43) to thereby form a wiring structure 130 for conducting signals. Thereby, a highly reliable electric contact between the electrically conductive coating 44 of the waveguide and the wiring structure 130 may be established by the electrically conductive lining 134 and the electrically conductive adhesive 47. The electrically conductive adhesive 47 may be cured, for instance by pressure and/or heating.

As an alternative to the described manufacturing process, it is also possible that the electrically conductive adhesive 47 is applied onto a lower main surface of the uppermost electrically conductive layer structure 41 and is connected to the upper surface of the electrically conductive lining 134 upon connecting the uppermost electrically conductive layer structure 41 with the annular dielectric layer 136 and the ridge 42, with the electrically conductive lining 134 thereon.

As a result of the described manufacturing method, the component carrier 100 according to an exemplary embodiment of the disclosure according to FIG. 8 is obtained.

The illustrated component carrier 100 is configured as printed circuit board with integrated waveguide and connected stripline. The component carrier 100 comprises the laminated layer stack 102 composed of electrically conductive layer structures 41 (preferably made of copper) and electrically insulating layer structures 40 (for instance made of prepreg). The hollow recess 43 in stack 102 is coated continuously with electrically conductive coating 44 (for instance also made of copper) and is thereby configured as waveguide. Advantageously, the entire sidewall 110 of the stack 102 delimiting the recess 43 has a roughness Rz of preferably not more than 5 μm. More specifically, the sidewall 110 may be preferably circumferentially closed and may extend completely and continuously vertically.

As already mentioned, the entire vertical sidewall 110 of the recess 43 is covered with the continuous electrically conductive coating 44. This provides a significantly better waveguide function in comparison with conventional metallic fence architectures. Furthermore, a patterned electrically conductive layer structure 41 is exposed at a bottom 48 of the recess 43. Also, the uppermost electrically conductive layer structure 41 according to FIG. 8 is a patterned layer.

Further advantageously, a horizontal surface of any of the electrically conductive layer structures 41 may have a roughness Rz of not more than 0.2 μm. Hence, the horizontal surfaces of at least one of the electrically conductive layer structures 41 may be even smoother than the surface of the sidewall 110 which can be accomplished by polishing, etc. Due to the skin effect, also a very low roughness Rz of said electrically conductive layer structures 41 may be highly advantageously for the high-frequency performance.

As furthermore shown in FIG. 8, the component carrier 100 may comprise—advantageously but optionally—an antenna structure 120 in the recess 43. Said antenna structure 120 may be preferably embodied as a free-standing structure in the recess 43, may thus be circumferentially spaced with respect to surrounding material of the stack 102 by an air gap of the hollow recess 43, and may comprise an arrangement of electrically conductive layer structures 41 (for example horizontal copper pads and copper vias) preferably embedded in dielectric material of at least one electrically insulating layer structure 40 for providing stability. By antenna structure 120, high-frequency signals 120 may be properly guided within the waveguide or hollow conductor.

Moreover, component carrier 100 comprises wiring structure 130 forming part of the uppermost electrically conductive layer structures 41 and being arranged on top of said recess 43. Signals may be guided through traces of wiring structure 130. More specifically, the wiring structure 130 may comprise a feedline structure 138 for coupling a signal between the wiring structure 130 and the waveguide.

Advantageously, ring-shaped ridge 42 (wherein ridge 42 may be alternatively configured as layer with central through hole) surrounds the recess 43 along its entire perimeter. For instance, ridge 42 may be made of a dielectric material, which allows to print or dispense material forming the ridge 42 on stack 102. As shown, the wiring structure 130 located on top of the ridge 42 is electrically coupled with the waveguide via the ridge 42, more specifically via electrically conductive lining 134 covering ridge 42. In the side view of FIG. 8, the electrically conductive lining 134 in combination with an electrically conductive layer structure 41 beneath the ridge 42 fully circumferentially surround the ridge 42. As can be taken from FIG. 8 as well, the wiring structure 130 is the uppermost of the electrically conductive layer structures 41.

Annular dielectric layer 136 has a central through hole and has the same height as the ridge 42 including its electrically conductive coating. The dielectric layer 136 may be arranged around the ridge 42 to achieve planarity.

Although not shown in FIG. 8, the poorly adhesive structure 124 may alternatively also remain covering bottom 48 of the recess 43 rather than being removed before completing manufacture of the component carrier 100. Advantageously, poorly adhesive structure 124 does not disturb high-frequency applications, so that maintaining poorly adhesive structure 124 as part of component carrier 100 may allow to skip a separate process of removing poorly adhesive structure 124.

Still referring to FIG. 8 (see also FIG. 20), the illustrated component carrier 100 comprises the recess 43 being configured as a waveguide-type cavity. As shown, a plurality of edges 67 delimit the recess 43 which are formed by electrically conductive material of the electrically conductive layer structure 41 and of the electrically conductive coating 44, and option-ally also by electrically conductive adhesive 47. The metallized edges 67 may be vertical ones and/or horizontal ones. Preferably, all edges 67 delimiting the recess 43 are formed by such electrically conductive material. Moreover, a plurality of (and preferably all four) vertical sidewalls 110 may be completely covered with said electrically conductive material, in particular of the electrically conductive coating 44.

According to FIG. 8, also a top wall and a bottom wall of the recess 43 are partially covered with electrically conductive material.

Optionally and although not shown, the recess 43 may be completely surrounded by electrically conductive material of the electrically conductive layer structures 41 and of the electrically conductive coating 44 (and optionally also by electrically conductive adhesive 47) with the only exception of an opening for feeding a radiofrequency signal (not shown in FIG. 8).

However, it may also be advantageously possible to directly provide a structures electrically conductive layer (in particular an antenna structure) at the waveguide bottom. Advantageously, the patterned (for instance antenna) structure can be placed on any sidewall of the recess, wherever needed or desired.

By the metallic coverage of corners, edges 67 and faces (in particular sidewalls 110) delimiting the cavity-type recess 43 forming a waveguide, a metallic cage may be created which maintains radiofrequency waves within the recess 43 during operation of the component carrier 100. This avoids signal loss and increases the signal transmission quality.

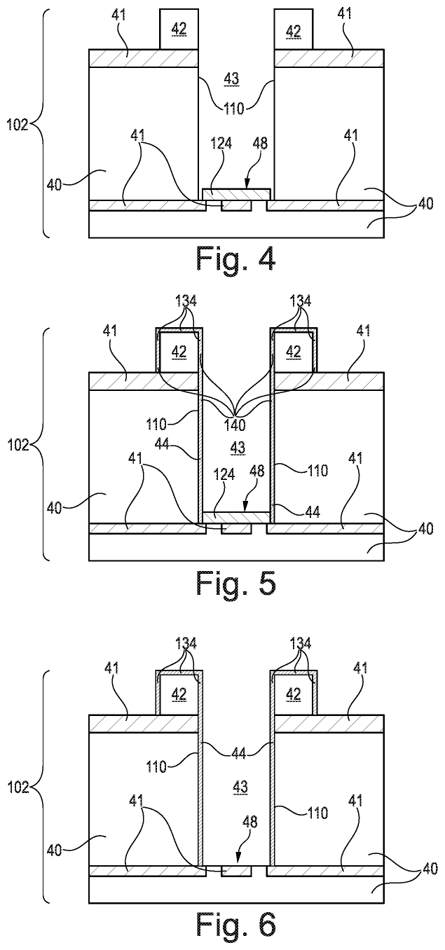

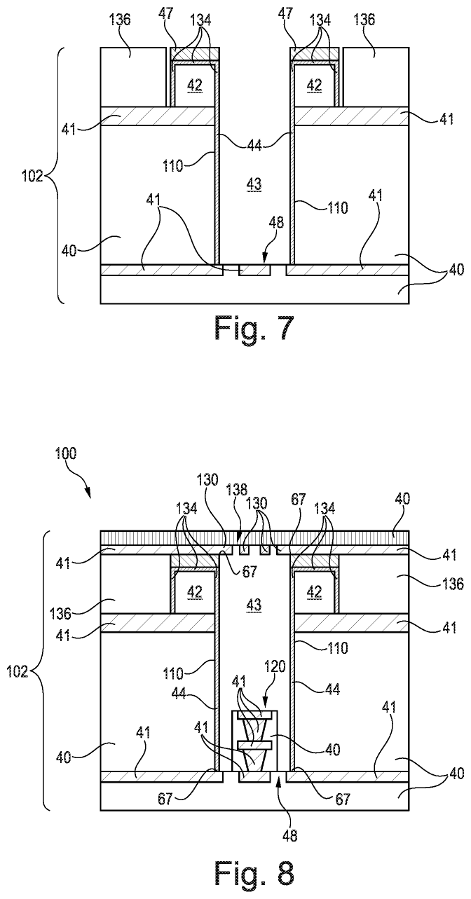

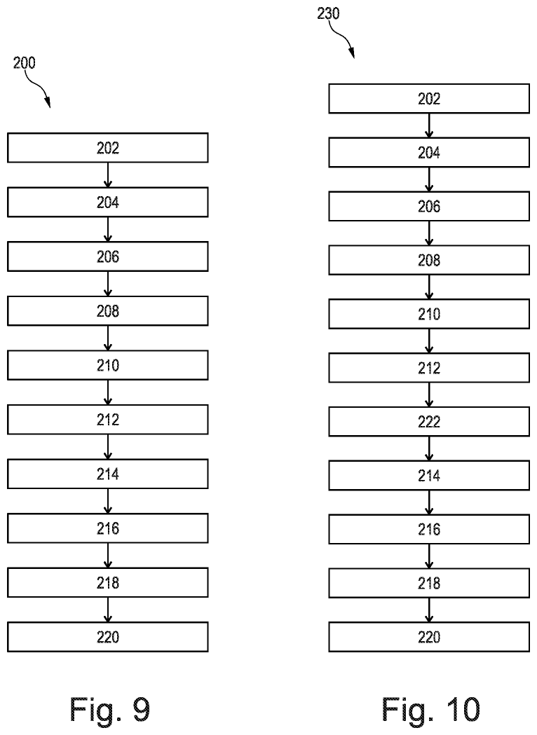

FIG. 9 is a flow diagram 200 of a method of manufacturing a component carrier 100 according to an exemplary embodiment of the disclosure. More specifically, a manufacturing method for providing a structured metal-coated hollow conductor and a transition between a strip conductor and a hollow conductor is shown in FIG. 9.

First, a copper layer at a bottom 48 of the structured hollow conductor to be manufactured is structured, see block 202 in FIG. 9. Methods of structuring the copper layer include and are not limited to etching methods, printing methods and mechanical processes for structuring.

Referring to a block 204, a poorly adhesive structure 124 and a laser stop structure 128 may then be printed on the bottom 48 of the recess 43 to be produced. After the process according to block 202, the previously structured copper layer, which represents the bottom 48 of the structured hollow conductor, is covered in the area of the hollow conductor to be provided with a chemical compound which represents a poorly adhesive structure 128 for the other layer structures 40, 41. Preferably, the poorly adhesive structure 124 is made of a hydrophobic material. This is advantageous, as the hydrophobic behavior leads to a decreased wettability, which is believed to promote a limited or even completely eliminated copper deposition on such films. At the same time, the poorly adhesive structure 124 is inert in a subsequent metallization process and is not coated in a chemical copper metallization process. These chemical compounds include, but are not limited to lipids, waxes, alcohols, lipid acid esters, and their mixtures, various polymers wie PP, PEEK, PEK, PVC, PS, fluorocarbons, PFC, PCTFE, fluoroelastomers, silicones, PFA, fluoropolymers such as polytetrafluoroethylene (PTFE), polyvinylidene fluoride (PVDF) and their polymers. Particularly preferred compounds are fluorocarbon compounds which comprise PTFE, PFC, PCTFE or fluoroelastomers or wax compounds.

In addition to the above-mentioned compounds of the poorly adhesive structure 124 (functioning as adhesion prevention material), organic and/or inorganic sulfur, phosphorus or nitrogen containing compounds can be added which act as catalysts for complexing agents during the catalytic deposition of metals (such as palladium, Pd—Sn, Pt, or Ag) and thereby prevent formation of the chemical copper metal layer. It may also be possible to print a combination of the above-mentioned compounds on the area of the structured bottom 48 of the hollow conductor according to an embodiment of the disclosure.

Referring to a block 206, further copper layers and prepreg layers may then be attached and connected by lamination for creating a further build-up of the component carrier 100 to be manufactured. Thus, further layer structures 40, 41 (such as copper layers and prepreg layers) of the hollow conductor are connected to the stack 102. The copper layer under the copper top layer of the structured hollow conductor can be structured and provided with laser holes.

Thereafter, a ridge 42 may be printed and cured on the uppermost copper layer of the stack 102 in which a recess 43 is to be formed (compare block 208). Hence, the ridge 42 is applied in the region of the cavity or recess 43 on the uppermost copper layer under the copper cover layer. Materials for the elevation or ridge 42 include and are not limited to varnishes, polymer mixtures, resins or resin mixtures, plug-in paste, solder stop varnish, polymers, and resins as well as resin mixtures which are stable in chemical copper processes of PCB manufacture.

The manufacturing processes for the creation of the ridge 42 can be carried out by a printing process and may include screen printing, three-dimensionally printing or other printing methods, in particular having an accuracy of less than ±5 μm, preferably having an accuracy of less than ±2 μm along x-, y- and z-axis. After printing, the ridge 42 may be subjected to a curing process. The curing process may be adapted to the applied material and can include the following processes: ultraviolet radiation, microwave radiation or thermal curing in an oven at a temperature in a range from 50° C. to 150° C. The metallization processes include and are not limited to a chemical copper process, a galvanic copper process, an electroless nickel immersion gold process and a chemical silver process.

Block 210 indicates a separation process (preferably by laser cutting) and subsequent activation of sidewalls 110 of the stack 102 as well as a removal of a material piece 142 in the center of the recess 43. After curing the ridge 42, a material piece 142 may be cut out from the stack 102 for exposing sidewalls 110 of the stack 102 by carrying out a precise separation method, preferably a laser cutting process. The ridge 42 as well as the underlying prepreg layers may be cut up to the laser stop position defined by laser stop structure 128. If laser cutting is used as a separation method, it is for instance possible to use a CO₂ laser or a UV laser. Preferably, pulsed laser beams (in particular nanosecond pulses, picosecond pulses or even femtosecond pulses) or alternatively continuous laser beams can be used. The cutting width of the laser cutter may be in the range from 10 μm to 30 μm, preferably less than 25 μm, especially preferably less than 20 μm. The accuracy of the laser cutting process may be ±30 μm, preferably ±20 μm, most preferably less than ±18 μm. An advantage of the method according to an embodiment of the disclosure is to produce the structured hollow conductor by cutting out a material piece 142 along sidewall 110 of the hollow conductor from stack 102 in the separation process. Therefore, no sidewall misalignment or edge can arise from layer offset in the hollow conductor.

According to the above-mentioned precise separation method, which includes, for example, a laser cutting process, a plasma smear process can be carried out to oxidize or activate cut-out sidewalls 110 of the structured cavity or recess 43 according to an embodiment of the disclosure. By taking this measure, it may be possible to properly prepare the sidewalls 110 for the chemical copper process. At the same time, laser holes of the outer copper layer can be cleaned with the plasma process, and the surface can be oxidized or activated for a chemical copper process. Usable gases of the plasma process include pure gases and their mixtures. As gas(es), it is possible to use for example oxygen, argon, helium, carbon tetrafluoride carbon, hydrogen and/or nitrogen.

After the precise separation process and plasma activation, the cut-out material piece 142 in the middle of the cavity or recess 43 is removed from the stack 102.

As shown by block 212, a metallization process may selectively apply metal on sidewalls 110 of the recess 43, preferably for creating a chemical copper structure and a galvanic copper structure. Hence, it may be possible to selectively cover the sidewalls 110 of the resulting structured hollow conductor and at the same time of the ridge 42 by a metallization method which, for example, includes chemical copper formation, but is not limited to this. Subsequently, said chemical copper may be covered with galvanic copper as well as chemical silver, chemical tin or a nickel-gold surface. During the chemical copper metallization process, the structured metal on the bottom 48 of the hollow conductor is not coated with the copper and remains protected by its coating with a poorly adhesive structure 124. If a chemical copper process is carried out as a metallization process, a galvanic copper structure can then be formed selectively on the sidewalls 110 of the structured hollow conductor.

Thereafter, the poorly adhesive structure 124 or protection layer may be removed from the patterned bottom 48 of the recess 43, compare block 214. After the formation of metal selectively on sidewalls 110 of the recess 43 constituting the waveguide or hollow conductor, the non-metallized poorly adhesive structure 124 (which may be embodied as adhesion prevention layer) at the bottom 48 of the structured hollow conductor may be removed. Appropriate processes for said removal are aqueous and acidic processes or plasma etching methods capable of removing the poorly adhesive structure 124. It may also be possible to carry out thermal procedures to evaporate the poorly adhesive structure 124.

Alternatively, it may also be possible that the poorly adhesive structure 124 remains on the structured hollow conductor at the bottom 48 of the recess 43 and is not removed, if a removal is not necessary for the use of the structured hollow conductor according to an embodiment of the disclosure. Advantageously, no significant signal loss arises in high frequency applications by the poorly adhesive structure 124 which therefore does not impair the function of the hollow conductor. An example of a poorly adhesive structure 124 or adhesive prevention layers that can remain in the hollow conductor without compromising the high-frequency properties of the component carrier 100 are coatings of fluoropolymers, since these have a low dielectric constant.

As shown by block 216, a copper layer around the recess 43 may then be patterned. After the removal of the non-coppered poorly adhesive structure 124 at the bottom 48 of the structured hollow conductor according to an embodiment of the disclosure, an outer copper layer may be structured. Dry resist or liquid resist can be used for this purpose, wherein the cavity or recess 43 of the structured hollow conductor can be covered during this structuring process in order to be protected during the etching process.

Referring to block 218, the patterned surfaces and the sidewall 110 of the recess 43 may then be subjected to one or more end surface processes (such as chemical tin, chemical silver, ENIG, ENIPIG, hard gold and/or OSP). In addition to the copper structuring, the structured copper surfaces at the bottom 48 of the structured hollow conductor and the selectively coppered sidewalls 110 may be additionally metallized by a final surface process. For this purpose, it may be for example possible to carry out a chemical tin process, to silver-plate by a chemical silver process, to gold-plate by an ENIG process, or to coat with an organic coating by means of an OSP process or with compounds such as at least one fluorocarbon compound which includes PTFE, PFC, PCTFE or a fluoroelastomer.

As a method variant to the copper structuring process, the structured copper surfaces at the bottom 48 of the structured hollow conductor can continue to remain protected by the poorly adhesive structure 124. The selectively coppered sidewalls 110 may be additionally metallized by a final surface process for instance using a chemical tin process, silver plating by a chemical silver process, gold plating by an ENIG process or coating by an OSP process with an organic material.

In order to close the recess 43 and finish the structured hollow conductor according to an embodiment of the disclosure, a cut-out prepreg (which may have the same height as the coppered ridge 42) may be placed around the coppered ridge 42. Subsequently, the structured hollow conductor according to an embodiment of the disclosure may be provided with an electrically conductive adhesive 47 (such as an electrically conductive silver or copper paste) which may be printed on a structured copper layer in the area of the ridge 42. The coppered sidewall 110 may then be closed by pressing one or more additional layers onto a top side of the recessed stack 102 in a pressing process.

In particular, the so obtained structured hollow conductor can be used for the connection between at least one antenna and at least one chip used in the GHz or THz frequency range. Additionally or alternatively, it may be possible to use the obtained component carrier 100 with hollow conductor for further applications such as the conduction of light or sound waves, gases and liquids. What concerns high-frequency applications, such a component carrier 100 with hollow conductor may have a high bandwidth and may show only low signal losses.

FIG. 10 is a flow diagram 230 of a method of manufacturing a component carrier 100 according to another exemplary embodiment of the disclosure. Substantially, the flow diagram 230 differs from flow diagram 200 by an additional block 222 between blocks 212 and 214.

In FIG. 10, a variant of the manufacturing method according to another embodiment of the disclosure it is shown for the preparation of a structured hollow conductor and a transition between a strip conductor and a hollow conductor.

After the precise printing process (preferably with a tolerance of less than +2 μm) for applying the ridge 42 and after curing the ridge 42 according to block 208, a precise separation process for separating a material piece 142 above the poorly adhesive structure 124 is carried out twice in blocks 210 and 222 between which a metallization process according to block 212 may be carried out. Preferably, the precise separation process according to blocks 210, 222 may be carried out by laser cutting. In the first precise separation process according to block 210, which can comprise a laser cutting process, one or more parts of the structured hollow conductor according to an embodiment of the disclosure may be precisely cut out which is or are to be covered with chemical copper. Those areas of the structured hollow conductor according to an embodiment of the disclosure which should remain free of metal (such as Cu, Cu—Ag, Cu—Sn, Cu—Ni—Au) are cut out in the first precise separation process with smaller dimensions. For instance, the first precise separation process may be a laser cutting process cutting out a structure which may be smaller (for example 20 μm to 100 μm smaller) than a material piece cut out in a subsequent second precise separation process. After a metallization process (which can for instance encompass a chemical copper, an electroplating copper, a chemical silver, a chemical tin, an OSP or an ENIG process) and a selective metal formation on the sidewalls 110 of the structured hollow conductor (see block 212), the previously smaller cut-out parts of the metallized sidewalls 110 may be cut away in a second precise separation process (such as for example a second laser cutting process). The second laser cutting process according to block 222 serves to expose signal lines in the hollow conductor to enable the functionality of the structured hollow conductor according to an embodiment of the disclosure. After the second precise separation process (such as a further laser cutting process), a further material piece is removed inside the structured hollow conductor.

After the copper formation in the chemical copper process and the galvanic copper process selectively on the sidewalls 110 of the recess 43 and at the ridge 42 of the structured hollow conductor according to an embodiment of the disclosure, the non-coated poorly adhesive structure 124 or adhesion prevention layer at the bottom 48 of the structured hollow conductor is removed. Said removal may be carried out by any process that sprays aqueous and/or solvent-containing solutions to remove the layer, or by thermal processes or by plasma etching processes, to etch or evaporate the layer.

The poorly adhesive structure 124 can alternatively remain in the structured hollow conductor according to an embodiment of the disclosure. For example, the poorly adhesive structure 124 may remain part of the component carrier 100 if the removal of said poorly adhesive structure 124 is not necessary for the use of the structured hollow conductor according to an embodiment of the disclosure. Advantageously, no significant signal loss arises by the poorly adhesive structure 124 which thereby does not impair the function of the hollow conductor. Correspondingly appropriate materials for the poorly adhesive structure 124 include, but are not limited to lipids, waxes, alcohols, fatty acid esters, and their mixtures, various polymers such as PP, PEEK, PEK, PVC, PS, fluorocarbons, PFC, PCTFE, fluoroelastomers, silicones, PFA, fluoropolymers such as polytetrafluoroethylene (PTFE), polyvinylidene fluoride (PVDF) and their polymer mixtures. In particular, fluorocarbon compounds which include PTFE, PFC or fluoroelastomers may be preferred.

In addition to the above-mentioned compounds in the poorly adhesive structure 124, organic and/or inorganic sulfur, phosphorus or nitrogen containing compounds can be added which may act as complexing agents during the catalytic deposition of metals (such as palladium, Pd—Sn, Pt, or Ag) and thereby prevent the build-up of the chemical copper metal layer. The poorly adhesive structure 124 can also be printed as a combination of above-mentioned compounds on the area of the structured bottom 48 of the hollow conductor according to an embodiment of the disclosure. The poorly adhesive structure 124 can also permanently remain at the bottom 48 of the hollow conductor without being removed, in particular when such a coating has a low dielectric constant and comprises at least one compound selected from the group of fluoropolymers (such as PTFE, PVDF, PFC or PCTFE).

After the removal of the non-coppered poorly adhesive structure 124 at the bottom 48 of the structured hollow conductor according to an embodiment of the disclosure, the outer copper layer may be structured. The cavity or recess 43 can be covered with photoresist, which may be applied for instance by printing. In addition to this structuring process, copper surfaces of the structured hollow conductor at the structured bottom 48 and the selectively coppered sidewalls 110 can be additionally metallized by a final surface process such as a chemical tin process, silver-plated by a chemical silver process or gold-plated by an ENIG process and coated with an organic protective layer by OSP or with a compound such as a fluorocarbon compound which comprises PTFE, PFC, PCTFE or fluoroelastomers.

In order to close the structured hollow conductor according to an embodiment of the disclosure, a cut-out prepreg can be placed around the coppered ridge 42 which has the same height as the coppered ridge 42. Subsequently, a structured copper layer on which an electrically conductive adhesive 47 (such as a silver or copper paste) is applied in the area around the metallized sidewalls 110, is applied to close the recess 43 and is pressed with the stack 102 by a printed circuit board pressing process. In addition to the structuring, structured copper surfaces of the top layer of the structured hollow conductor according to an embodiment of the disclosure can additionally be metallized by a final surface process such as a chemical tin process, silver-plated by a chemical silver process or gold-plated by an ENIG process or provided with an organic protective layer by an OSP process or with a connection in form of at least one fluorocarbon compound which comprises PTFE, PFC, PCTFE or fluoroelastomers. The electrically conductive adhesive 47, which can comprise copper or silver particles, may be applied to the upper copper layer after the final surface process and before the pressing process.

The obtained structured hollow conductors can be used for the connection between at least one antenna and at least one chip used in the GHz or THz frequency range. Further possible applications include and are not limited to the conduction of light or sound waves, gases and liquids and have a higher bandwidth and lower signal losses as compared with conventional approaches.

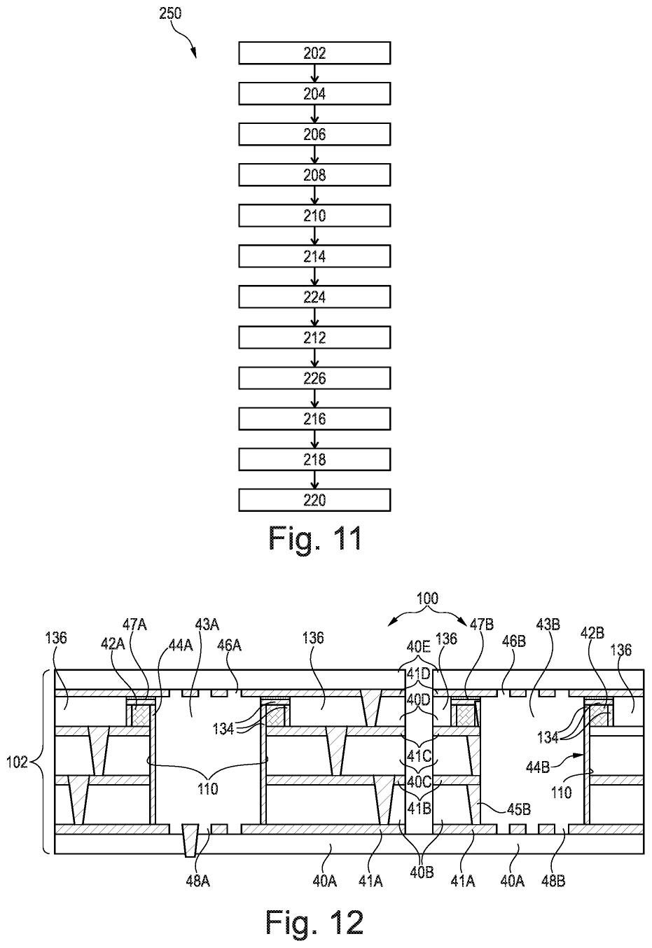

FIG. 11 is a flow diagram 250 of a method of manufacturing a component carrier 100 according to still another exemplary embodiment of the disclosure. Substantially, the flow diagram 250 differs from flow diagram 200 by additional blocks 224 and 226 between blocks 214 and 216 and by a shift of block 212 between blocks 224 and 226. According to FIG. 11, poorly adhesive structure 124 is removed after having removed material piece 142 from stack 102, and another protection layer is formed on the bottom 48 for protecting a structured electrically conductive layer structure 41 on the bottom 48 against metallization during a subsequent electroless plating process. Said protection layer may also be poorly adhesive or non-sticky for metal, in particular for metal applied by electroless plating.

Block 224 indicates a process of printing protection layer on patterned bottom 48 of the recess 43. Block 226 indicates a removal of the protection layer from the patterned bottom 48 of the recess 43 after electroless plating and after optionally additionally galvanically plating according to block 212.

Hence, FIG. 11 shows a further variant of the method for manufacturing a structured hollow conductor and the transition between a strip conductor and a hollow conductor according to still another embodiment of the disclosure.

In said embodiment, the poorly adhesive structure 124 is removed after the (in particular first) laser cutting process. Thereafter, a protective film is applied as the protection layer to the structured bottom 48 of the hollow conductor. The protective film is inert in the subsequent chemical copper metallization process and is not coated with metal. Exemplary materials for this protective film are greases, waxes, alcohols, fatty acid esters, and their mixtures, various polymers such as PP, PEEK, PEK, PVC, PS, fluorocarbons, PFC, PCTFE, fluoroelastomers, silicones, PFA, fluoropolymers such as polytetrafluoroethylene (PTFE), polyvinylidene fluoride (PVDF) and their polymer mixtures.

In addition to the above-mentioned compounds of the adhesion prevention material, organic and/or inorganic sulfur, phosphorus or nitrogen containing compounds can be added which act as complexing agents during the catalytic deposition of metals (such as palladium, Pd—Sn, Pt, or Ag) and thereby prevent the formation of a chemical copper metal layer thereon. Such a poorly adhesive structure can also be printed as a combination of the above-mentioned compounds on the area of the structured bottom 48 of the hollow conductor according to an embodiment of the disclosure.

After the selective metallization process, the protective film with suitable solvents is removed from the structured bottom 48 of the structured hollow conductor according to an embodiment of the disclosure with a spray process or with a plasma etching process with oxygen- or hydrogen-containing plasma gases and their mixtures. In addition, at least one vent hole may be included for pressure equalization or for filling gases or for the evacuation of the hollow conductor.

Copper surfaces of the structured hollow conductor such as the structured bottom 48 and the selectively copper-plated sidewalls 110 as well as a structured copper top layer can additionally be metallized by a final surface process which can be a chemical tin process, silver plating by a chemical silver process, gold-plating by an ENIG process, or treatment by an OSP process for applying an organic protective layer. Also, ENIPIG or hard gold processes may be executed for forming a protective layer.

An obtained structured hollow conductor can be used for the connection between at least one antenna and at least one chip used in the GHz or THz frequency range, and/or may be used for further applications such as the conduction of light or sound waves, gases, and liquids. Advantageously, a component carrier 100 with a corresponding waveguide may have a higher bandwidth and lower signal losses than conventional devices.

In the following FIG. 12 to FIG. 19, exemplary embodiments of component carriers 100 with structured metallized hollow conductors and transitions between conductor strips and hollow conductors will be described.

FIG. 12 illustrates a component carrier 100 according to an exemplary embodiment of the disclosure.

In FIG. 12, a structured hollow conductor in cavity or recess 43A, 43B according to an embodiment of the disclosure is shown. The illustrated component carrier 100 shows copper layers 41A, 41B, 41C and 41D as well as prepreg layers 40A, 40B, 40C, 40D and 40E. The thickness of the copper layers 41A, 41B, 41C and 41D can be between 10 μm and 35 μm and the thickness of the prepreg layers 40A, 40B, 40C, 40D and 40E can be between 20 μm and 200 μm. Ridges with copper-plated edge connected to the copper layer 41D are shown with reference signs 42A and 42B. The copper-coated sidewalls of the structured hollow conductor are shown with reference signs 44A and 44B. A structured bottom of the hollow conductor or waveguide is shown with reference signs 48A and 48B. Furthermore, a structured sidewall 45B is shown which is formed by copper structures of laser holes filled with copper and by one or more structured copper layers 41B, 41C and 41D. Component carrier 100 according to FIG. 12 can be manufactured by a manufacturing process as it is shown in FIG. 10 and may involve a first and a second laser cutting process. The copper surfaces of the structured hollow conductor can be refined after removal of the poorly adhesive structure 124 (which is not shown in FIG. 12 to FIG. 19, but may be present in other embodiments of component carriers 100) and after structuring the copper layer 41D with various end surface processes such as chemical tin, ENIG, chemical silver or OSP. At least one prepreg 40D may be applied. The prepreg 40D has the same layer thickness as that of the metallized edge of the ridge and contains cut openings corresponding to a size of the edges of the ridge. Said prepreg 40D is placed around the edges of the ridge 42A, 42B during the manufacturing process. Thereafter, a structured copper layer 41D—on which an electrically conductive silver or copper-containing adhesive 47A, 47B may be applied in the area of the metallized ridge—is applied. Thereafter, a prepreg 40E is pressed onto the top in a pressing process and closes the structured hollow conductor. In addition, at least one vent hole may be included for pressure equalization or for filling gases or for the evacuation of the recess(es) of the hollow conductor.

According to the embodiment of FIG. 12, some of the electrically conductive layer structures 41 are exposed at the respective sidewall 110 in cavity 43B.

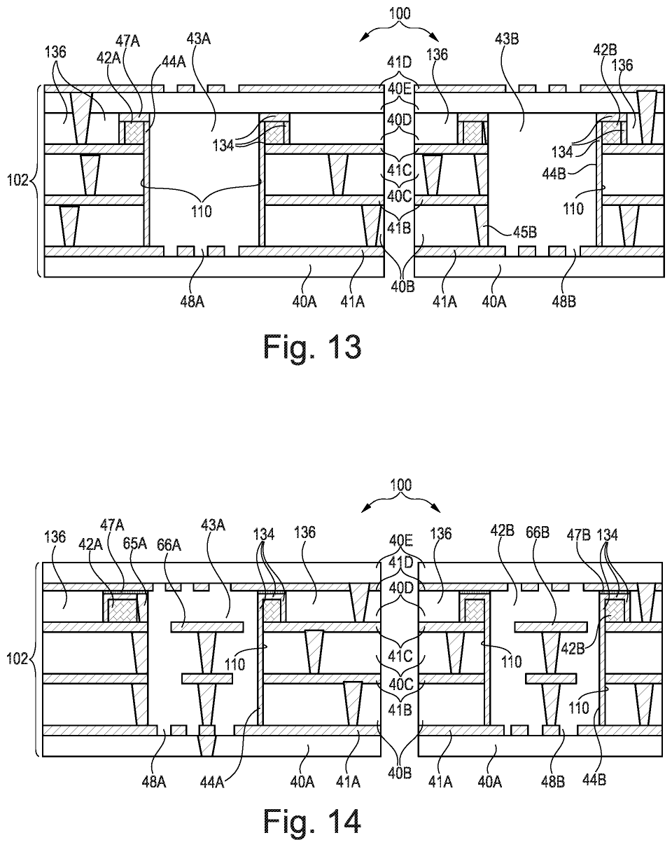

FIG. 13 illustrates a component carrier 100 according to another exemplary embodiment of the disclosure.

In FIG. 13, a component carrier 100 with a structured hollow conductor in the cavities or recesses 43A, 43B according to another embodiment of the disclosure is shown. The illustrated printed circuit board shows the copper layers 41A, 41B, 41C and 41D as well as the prepreg layers 40A, 40B, 40C, 40D and 40E. The thickness of the copper layers can be between 10 μm and 35 μm and the prepreg thickness of the prepreg layers can be between 20 μm and 200 μm. The copper-plated polymer ridge on the copper layer 41C is shown with reference signs 42A and 42B. The copper-plated sidewalls of the structured hollow conductor are shown with reference signs 44A and 44B. The structured bottom of the copper layer 41A of the structured hollow conductor is shown with reference signs 48A and 48B. Furthermore, a structured sidewall 45B is shown which represents a copper structure of laser holes filled with copper and at least one structured copper layer 41B, 41C. The formation of the structured, non-coppered sidewall 45B of the structured hollow conductor may be carried out by a manufacturing process with a second laser cutting process as shown in FIG. 10. The structured hollow conductor can be refined after removing the internal poorly adhesive structure (which is inert in the chemical copper process). Said refining can be carried out with various end surface processes such as chemical tin, ENIG, chemical silver or OSP. At least one prepreg 40D can be attached around ridges 42A, 42B. The prepreg 40D has the same layer thickness as that of the metallized edge of the ridge 42A, 42B, contains cut openings in the size of the edges of the ridge 42A, 42B, and can be placed around the edges of the ridge 42A and 42B respectively during the manufacturing process. Thereafter, the structured hollow conductor is closed with the structured copper layer 41D and a prepreg 40E which may be pressed onto the stack 102 in a pressing process.

FIG. 14 illustrates a component carrier 100 according to still another exemplary embodiment of the disclosure.

In FIG. 14, component carrier 100 with a structured hollow conductor in a cavities or recesses 42A, 42B is shown. The component carrier 100 has a stack 102 comprising copper layers 41A, 41B, 41C and 41D as well as prepreg layers 40A, 40B, 40C, 40D and 40E. The thickness of the copper layers can be between 10 μm and 35 μm and the thickness of the prepreg layers can be between 20 μm and 200 μm. The copper plated ridges on the copper layer 41C are shown with reference signs 42A and 42B. The copper-plated sidewalls of the structured hollow conductor are shown with reference signs 44A and 44B. The structured copper layer 41A at the bottom of the structured hollow conductor is shown with reference signs 48A and 48B. Chemical compounds which may be included in a poorly adhesive structure (which is already removed according to FIG. 14 and which is used for forming recesses 43A, 43B as well as for protecting patterned bottoms 48A and 48B against metallization) may be for example lipids, waxes, alcohols, fatty acid esters, and their mixtures, various polymers such as PP, PEEK, PEK, PVC, PS, fluorocarbons, PFC, PCTFE, fluoroelastomers, silicones, PFA, fluoropolymers such as polytetrafluoroethylene (PTFE), polyvinylidene fluoride (PVDF) and their polymer mixtures.

In addition to the above-mentioned compounds of the poorly adhesive structure 124, organic and/or inorganic sulfur, phosphorus or nitrogen containing compounds can be added which act as complexing agents during the catalytic deposition of metals (such as palladium, Pd—Sn, Pt, or Ag) and thereby prevent the build-up of the chemical copper metal layer at patterned bottoms 48A and 48B. The poorly adhesive structure 124 can also be printed as a combination of several of the above-mentioned compounds on the area of the structured bottom of the hollow conductor.

Furthermore, structured sidewalls 65A, 66A and 66B are shown which represent a copper structure of laser holes filled with copper and at least one structured copper layer 41A, 41B, 41C and 41D. The structured, non-coppered sidewall 65A of the structured hollow conductor can be created by a manufacturing process as described referring to FIG. 10, i.e. implementing a second laser cutting process in addition to a first one. The structured hollow conductor can be refined after removing the poorly adhesive structure 124 by plasma etching (and optionally after structuring of copper layer 41D) with various end surface processes such as chemical tin, ENIG, chemical silver or OSP. At least one prepreg 40D may be attached which has the same layer thickness as that of the metallized edge of the ridge and contains cut openings in the size of the edges of the ridge. Prepreg 40D may be placed around the edges of the ridge 42A and 42B, respectively, during the manufacturing process. Thereafter, the structured copper layer 41D—on which an electrically conductive silver or copper-containing adhesive 47A, 47B is applied in the area of the metallized ridge—is applied. A prepreg 40E closes the structured hollow conductor and is pressed in a pressing process.

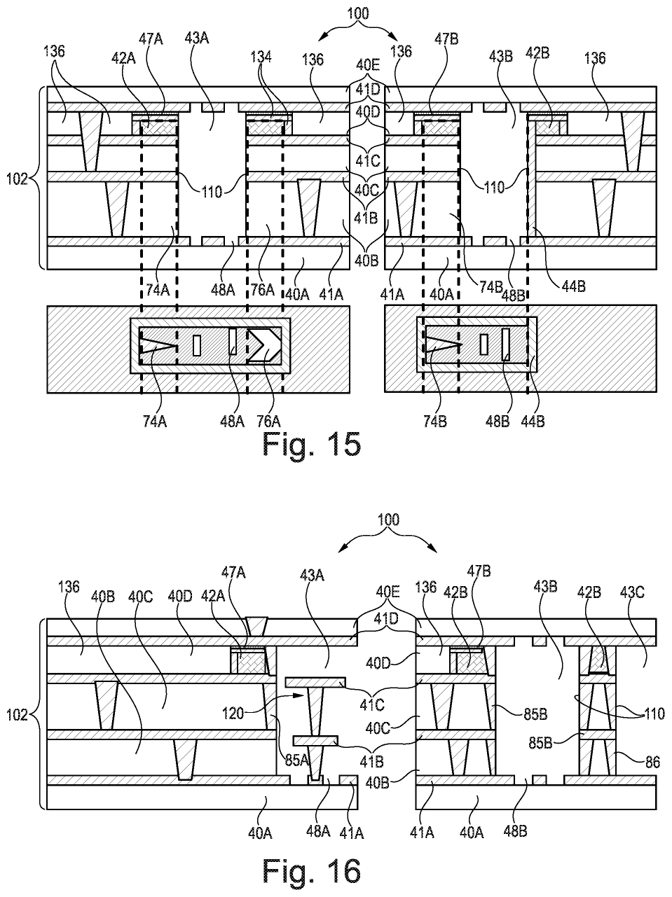

FIG. 15 illustrates a component carrier 100 according to yet another exemplary embodiment of the disclosure.

In FIG. 15, a side view (on top of FIG. 15) with closed top layers and a top view (on the bottom of FIG. 15) in an open state of a component carrier 100 with a structured hollow conductor according to still another embodiment of the disclosure are shown. The structured hollow conductor according to the described embodiment of the disclosure is shown with recesses 43A, 43B. The stack 102 of the printed circuit board-type component carrier 100 comprises copper layers 41A, 41B, 41C and 41D as well as prepreg layers 40A, 40B, 40C, 40D and 40E. The thickness of the copper layers can be between 10 μm and 35 μm and the thickness of the prepreg layers can be between 20 μm and 200 μm. The copper-plated ridge on the copper layer 41C is shown with reference signs 42A and 42B. The selectively non-coppered walls of a transition element from a stripline to the hollow conductor are shown with reference signs 74A, 74B and 76A. The structured bottom in the copper layer 41A of the structured hollow conductor is shown with reference signs 48A and 48B. The formation of the selectively non-coppered walls of the transition element from stripline in the structured hollow conductor 74A, 74B and 76A can be accomplished by a manufacturing process as shown in FIG. 10 which comprises a second laser cutting process in addition to a first laser cutting process. The structured hollow conductor can be coated after the removal of the poorly adhesive structure (which is inert in the chemical copper process) by plasma etching and after structuring the copper layer 41D with various end surface processes (such as chemical tin, ENIG, chemical silver or OSP or with a compound consisting of at least one fluorocarbon compound which comprises PTFE, PFC, PCTFE or fluoroelastomers). At least one prepreg 40D may be attached to the stack 102 for planarization. The prepreg 40D has the same layer thickness as that of the metallized edge of the ridge and contains cut openings in the size of the edges of the ridge. The prepreg 40D can be placed around the edges of the ridge 42A and 42B during the manufacturing process. Thereafter, a pressing process can be carried out with structured copper layer 41D on which an electrically conductive silver or copper-containing adhesive 47A, 47B is applied in the area of the metallized ridge. The formed recess can be closed by structured copper layer 41D and a prepreg 40E by a pressing process. In addition, at least one vent hole may be included for pressure equalization or for filling gases or for the evacuation of the hollow conductor.

FIG. 16 illustrates a component carrier 100 according to yet another exemplary embodiment of the disclosure.

In FIG. 16, the structured hollow conductor is shown in a side view with reference signs 43A, 43B and 43C. The illustrated printed circuit board-type component carrier 100 comprises copper layers 41A, 41B, 41C and 41D as well as prepreg layers 40A, 40B, 40C, 40D and 40E. The thickness of the copper layers can be between 10 μm and 35 μm and the thickness of the prepreg layers can be between 20 μm and 200 μm. The copper-plated ridge on the copper layer 41C is shown with reference signs 42A and 42B. The structured bottom at the copper layer 41A of the structured hollow conductor is shown with reference signs 48A and 48B. The creation of the selectively non-coppered sidewalls of a transition element of a stripline to the structured hollow conductor, indicated with reference signs 85A, 85B and 86, can be accomplished by a manufacturing process as described referring to FIG. 10. The structured hollow conductor can be refined after removing the poorly adhesive structure (which is inert in the chemical copper process) and structuring the copper layer 41D with various end surface processes such as chemical tin, ENIG, chemical silver or OSP. The structured hollow conductor can be covered with at least one prepreg 40D. The prepreg 40D has the same layer thickness as that of the metallized edge of the ridge and contains cut openings in the size of the edges of the ridge. The prepreg 40D is placed around the edges of the ridge 42A and 42B during the manufacturing process. Thereafter, the structured copper layer 41D—on which an electrically conductive silver or copper-containing adhesive 47A, 47B is applied at an underside in the area of the metallized ridge—is applied and a prepreg 40E closes the structured hollow conductor in a pressing process. FIG. 16 shows a U-shaped patch antenna structure 120 at the edge of recess 43A.

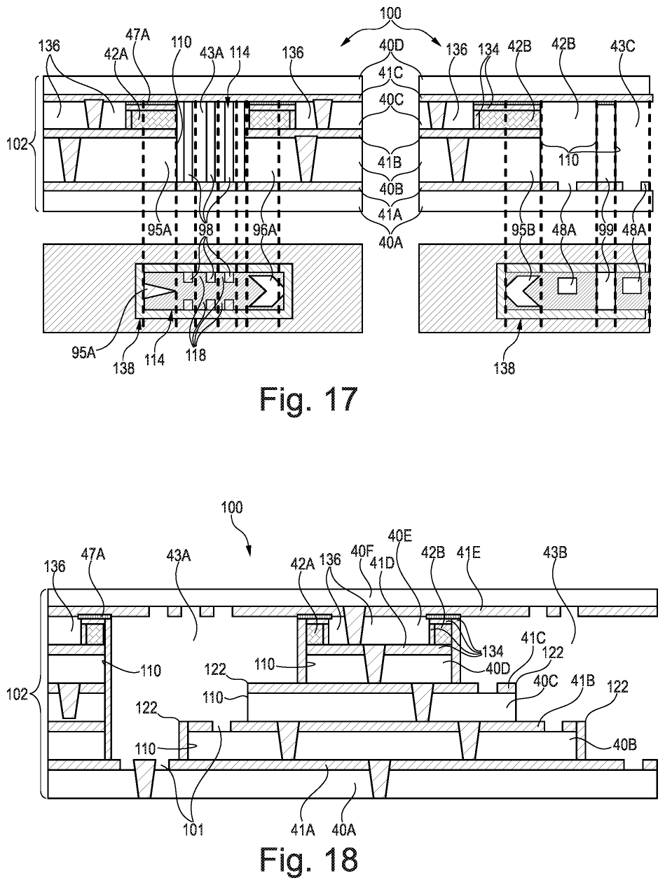

FIG. 17 illustrates a component carrier 100 according to yet another exemplary embodiment of the disclosure.

The embodiment of FIG. 17 comprises a frequency filter structure 114 at the recess 43A. Said frequency filter structure 114 is formed by a plurality of webs 98 of electrically insulating layer structures 40 at the sidewall 110, and by an electrically conductive structure 118 which may be formed on and/or between the webs 98. For instance, the frequency filter structure 114 may fulfil a high-pass, a low-pass or a band-pass filter functionality concerning high-frequency signals.

In FIG. 17, the structured hollow conductor is shown once with copper cover layer closed in a side view (see top of FIG. 17) and once in the open state in a top view. Recesses of the structured hollow conductor are shown with reference signs 43A, 43B and 43C. The stack 102 of the printed circuit board comprises copper layers 41A, 41B and 41C as well as prepreg layers 40A, 40B, 40C and 40D. The thickness of the copper layers can be between 10 μm and 35 μm and the thickness of the prepreg layers can be between 20 μm and 200 μm. The copper-plated ridge on the copper layer 41B is shown with reference signs 42A, 42B. The selectively non-coppered sidewalls of a transition element from a stripline to the hollow conductor are shown with reference signs 95A, 95B and 99. It is also possible, as indicated by reference sign 99, to provide interior sidewalls of the stack 102 without copper. The structured bottom in the copper layer 41A of the structured hollow conductor is shown with reference sign 48A. The formation of the non-coppered sidewalls of a transition element from a stripline to the hollow conductor (see reference signs 95A, 95B and 96A and 99 of the structured hollow conductor can be achieved by carrying out a manufacturing process according to FIG. 10 with a second laser cutting process. The structured hollow conductor can be refined after removing the poorly adhesive structure and structuring the copper layer 41B with various end surface processes such as chemical tin, ENIG, chemical silver or OSP. At least one further prepreg 40C may be applied which may have the same layer thickness as that of the metallized edge of the ridge and contains cut openings in the size of the edges of the ridge. The at least one further prepreg 40C is placed around the edges of the ridge 42A and 42B during the manufacturing process. Thereafter, the structured copper layer 41C (on which an electrically conductive silver or copper-containing adhesive 47A is applied in the area of the metallized ridge) and a prepreg 40D may close the structured hollow conductor, for instance by lamination.

FIG. 18 illustrates a component carrier 100 according to yet another exemplary embodiment of the disclosure.

In this embodiment, the circumferentially close sidewalls 110 have several steps 122.

In FIG. 18, a step-shaped structured hollow conductor is illustrated in a side view. The step-shaped hollow conductor is shown with recesses 43A, 43B. The shown printed circuit board configuration comprises copper layers 41A, 41B, 41C, 41D and 41E as well as prepreg layers 40A, 40B, 40C, 40D, 40E and 40F. The thickness of the copper layers can be between 10 μm and 35 μm and the prepreg thickness can be between 20 μm and 200 μm. The copper-plated ridges on the copper layer 41D are shown with reference signs 42A, 42B. The selectively non-coppered sidewalls of a transition element of a stripline at copper layer 41C of the structured stepped hollow conductors are shown at both ends of the prepreg 40C. The production of the selectively non-coppered sidewalls of the prepreg layer 40C of the transition element can be carried out by a manufacturing process according to FIG. 10. The structured bottom of the structured hollow conductor is shown in the copper layer 41A as well as in the copper layer 41B and with reference sign 101. The structured hollow conductor can be refined after removing the poorly adhesive structure (which is also inert in the chemical copper process) and structuring the copper layer 41D with various end surface processes such as chemical tin, ENIG, chemical silver or OSP. A prepreg 40E has the same layer thickness as that of the metallized edge of the ridge and contains cut openings in the size of the edges of the ridge. Prepreg 40E may be placed around the edges of the ridge 42A and 42B during the manufacturing process. Thereafter, structured copper layer 41E (on which an electrically conductive silver or copper-containing adhesive 47A is applied at an underside in the area of the metallized ridge) and a prepreg 40F may be laminated to the top of the stack 102 to thereby close the structured hollow conductor.

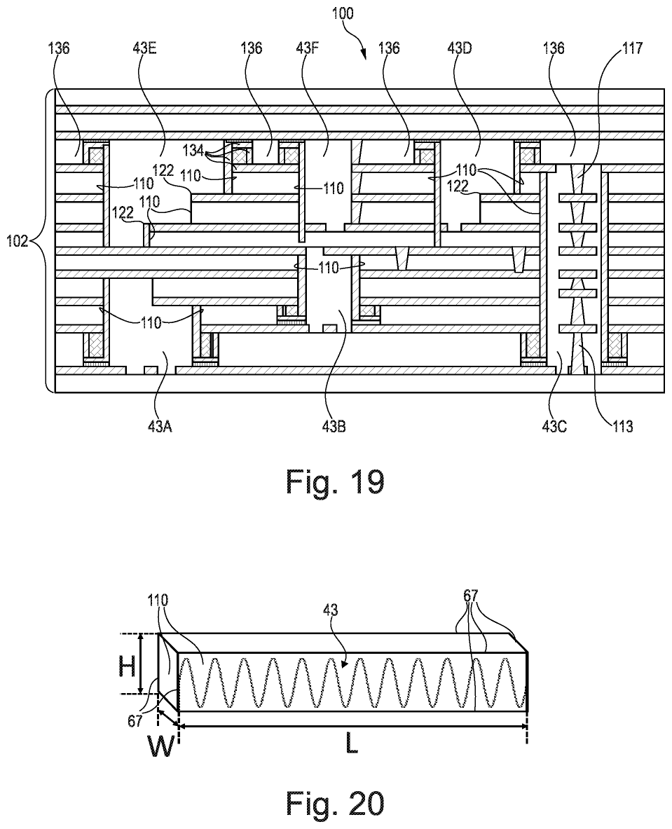

FIG. 19 illustrates a component carrier 100 according to yet another exemplary embodiment of the disclosure.

In FIG. 19, another embodiment with stepped structured hollow conductors is illustrated in a side view. Different geometries of recesses of the structured hollow conductors are shown with reference signs 43A, 43B, 43C, 43D, 43E, 43F. The selectively non-coppered sidewalls of a transition element of a stripline in copper layer relating to reference signs 113 and 117 of the structured stepped hollow conductor are shown in the cavity relating to reference sign 43C. The manufacture of the selectively non-coppered sidewalls as well as selectively non-coppered processes in some of the illustrated cavities may be carried out by a manufacturing process with several laser cutting processes of the type described referring to FIG. 10.

Structured bottoms and walls are shown in the structured hollow conductors according to recesses 43A, 43B, 43C, 43D, 43E, 43F. The copper structure 113 is connected to the bottom side of recess 43C via a copper layer and the copper structure 117 is connected to the top side of recess 43C via a respective copper layer.

The examples of structured metallized hollow conductors described referring to FIG. 12 to FIG. 19 and the corresponding manufacturing methods allow a precise mass manufacture and can be used particularly appropriately in a frequency range above 20 GHz, preferably over 28 GHz. These structured hollow conductors can be used in particular for the connection between at least one antenna and at least one chip or as a transition component between stripline and hollow conductor in the GHz or THz frequency range. Possible applications include and are not limited to the conduction of light or sound waves, gases and liquids and have a high bandwidth and low signal loss.

Exemplary embodiments of the disclosure relate to structured, metallized hollow conductors and transitions between a strip conductor and a hollow conductor integrated in a component carrier such as a printed circuit board (PCB). Furthermore, a corresponding manufacturing process is provided. In such a hollow conductor and transition, copper structures at the bottom of the hollow conductor and transition may be temporarily or permanently coated with at least one poorly adhesive structure such as an adhesive prevention or non-sticky layer. The latter may comprise or consists of at least one compound of the group of fluoropolymers such as PTFE or PVDF and may be advantageously inert in a chemical copper metallization process. A copper layer under a copper cover layer may be provided with at least one ridge in the area of the hollow conductor, which is preferably stable in the chemical copper formation process. The hollow conductor may be cut out in the area of the ridge preferably by at least one laser cutting process. A resulting edge of the ridge as well as sidewalls of the structured hollow conductor may be coated with chemical copper, wherein the structured, protected bottom is not metallized with chemical copper thanks to the poorly adhesive structure covering the structured bottom during chemical copper formation. In a subsequent structuring process, the hollow conductor may be covered. More specifically, at least one prepreg layer with opening may be placed around the coppered edges of the ridge. Said at least one prepreg layer may have the same height as the metallized edges of the ridge. A top layer comprising at least one structured copper layer and an electrically conductive adhesive in the area of the ridge may then be attached to the top side of the obtained stack.

For instance, the thickness of the ridge is in the range from 10 μm to 1000 μm, preferably from 15 μm to 800 μm. Preferably, the material of the ridge is stable during the chemical copper process and the PCB manufacture. For instance, said material can include varnishes, polymer mixtures, resins or resin mixtures, plug-in paste, solder stop varnish, polymers, various resins as well as resin mixtures.

For instance, the poorly adhesive structure may have a thickness in a range from 1 nm to 100 μm, preferably a thickness in a range from 2 nm to 80 μm. Moreover, the poorly adhesive structure may comprise at least one compound, which is chosen from the following chemical compounds: lipids, waxes, alcohols, fatty acid esters, and their mixtures, various polymers such as PP, PEEK, PEK, PVC, PS, fluorocarbons, PFC, PCTFE, fluoroelastomers, silicones, PFA, fluoropolymers such as polytetrafluoroethylene (PTFE), polyvinylidene fluoride (PVDF) as well as organic and/or inorganic sulfur, phosphorus or nitrogen-containing compounds which act as complex formation agent during the catalytic deposition of metals such as palladium, Pd—Sn, Pt, or Ag catalysts.

Preferably, the structured copper top layer may be covered in the area of the copper-plated sidewall with an electrically conductive connection material before the pressing process. For instance, the electrically conductive connection material can comprise silver and copper particles, preferably in the form of a paste. The electrically conductive connection material may be printed on the copper top layer or on the ridge in order to produce an electrical contact between the metallized sidewalls of the metallized hollow conductor and the copper top layer.

In one embodiment, the poorly adhesive structure (for instance configured as adhesive prevention layer) is used for the protection of the structured copper surface of the bottom of the hollow conductor against coverage with copper material during chemical copper formation. It is possible that this poorly adhesive structure is maintained or preserved during a further selective metallization of the copper sidewalls of the structured hollow conductor. Such coatings may be formed for example by final surface processes such as chemical silver, chemical tin, ENIG and/or OSP.

Preferably, the structured copper surface of the top layer may be coated by final surface processes such as chemical silver, chemical tin, ENIG or OSP.

FIG. 20 illustrates dimensions “L”, “W”, and “H” of a waveguide-type recess 43 of a component carrier 100 according to an exemplary embodiment of the disclosure.

As shown in FIG. 20, the width “W” and the length “L” of the recess 43 denote the horizontally extending axes of the cuboid recess 43. In other words, the width “W” and the length “L” of the recess 43 are the dimensions of the recess 43 in the two horizontal dimensions, whereas height “H” corresponds to a dimension of the recess 43 in a vertical direction according to FIG. 20, i.e. perpendicular to the main surfaces of the component carrier 100. Preferably, a difference between a maximum value and a minimum value of the width “W” along the length “L” does not exceed 75 μm, more preferably does not exceed 20 μm and most preferably does not exceed 15 μm, in order to ensure a low loss wave propagation (schematically indicated in FIG. 20 as oscillating wave) within the waveguide.

Technical effects correlated with the mentioned small width tolerance will be explained in the following: Without wishing to be bound to a specific theory, it is presently believed that the size and accordingly the dimensions of the cavity or recess 43 defining the waveguide are partly dependent on the wavelength of the signal to be transported. This pre-defined width “W” of the cavity or recess 43 should not deviate by more than 75 μm along the length “L” of the cavity, in particular not more than 20 μm, more particularly not more than 15 μm. It is believed that a low roughness Rz (for instance in a range from 15 μm to 75 μm) of sidewalls 110 delimiting the recess 43 may have a positive impact on the mentioned low width tolerance. The absolute value of the width “W” may depend on the wavelength of an electromagnetic signal to be transported by the waveguide.

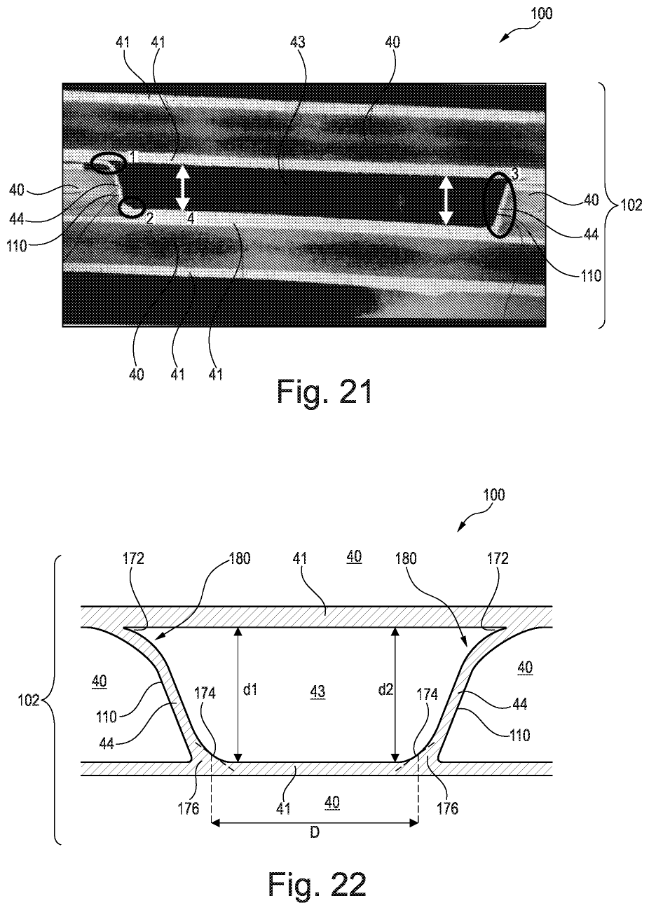

FIG. 21 illustrates a cross-sectional image of a manufactured component carrier 100 with interior waveguide-type recess 43 according to an exemplary embodiment of the disclosure. Hence, FIG. 21 shows a cross-section of a practically manufactured component carrier 100 obtained by carrying out a manufacturing process similar to FIG. 1 to FIG. 8 with properly adjusted manufacturing parameters (in particular in terms of laser cutting and metal deposition). FIG. 22 illustrates a cross-sectional view of a component carrier 100 with interior waveguide-type recess 43 according to an exemplary embodiment of the disclosure and corresponding to the image of FIG. 21. Several features of the component carrier 100 according to FIG. 21 are illustrated more schematically in FIG. 22 as a basis for the below description.

First referring to FIG. 21, the illustrated cross section of the hollow waveguide in form of metal cladded recess 43 shows some specific and advantageous features:

As indicated with “1” in FIG. 21, a curved shape of copper at the top edges of recess 43 may be obtained.

As indicated with “2” in FIG. 21, it is optionally possible to create a tilted copper structure at the bottom edges of recess 43. In the shown embodiments, this feature is more pronounced in the left bottom edge than in the right bottom edge.

As indicated with “3” in FIG. 21, a tapered sidewall 110 may be adjusted for the cavity forming the waveguide.

As indicated with “4” in FIG. 21, a difference of the height from one bottom edge to the other bottom edge is preferably not more than 20%, in particular not more than 10%.

More generally, and now referring to FIG. 22, the illustrated component carrier 100 comprises a laminated layer stack 102 composed of several electrically conductive layer structures 41 and several electrically insulating layer structures 40 being connected by the application of pressure and temperature, i.e. by lamination. A recess 43 is formed in an empty area of the stack 102 and is configured as a (in particular hollow or low DK-filled) waveguide. An electrically conductive coating 44 lines sidewalls 110 of the stack 102 which laterally delimit the recess 43.

As indicated with reference signs 180, the electrically conductive coating 44 is curved outwardly on an upper end of the sidewalls 110. This geometry may buffer mechanical stress occurring when laminating layer structures 41, 40 on top of the recess 43. Thus, the mentioned feature may improve the mechanical integrity of the component carrier 100.

As shown in FIG. 1 as well, a narrow beak-shaped extension 172 of the recess 43 is formed between the electrically conductive coating 44 and the electrically conductive layer structure 41 at the upper end of the sidewalls 110. Also, the beak-shaped extension 172 may have an advantageous stress damping and force balancing function during applying vertical pressing forces during lamination. Adjusting the properties of the beak-shaped extension 172, fine-tuning of the RF properties of the component carrier 100 may be achieved.

Again referring to FIG. 22, the recess 43 is delimited at a lower end of the sidewalls 110 by a tilted metallic section 174 formed in an interface region between the slanted or tilted electrically conductive coating 44 and a horizontal electrically conductive layer structure 41. This is indicated with slanted dotted lines in FIG. 22. In addition, the electrically conductive coating 44 tapers downwardly in a central part of the sidewalls 110. This outwardly tapering geometry of the recess 43 in a vertical direction also contributes to a proper mechanical force distribution without significantly influencing the high-frequency properties of the waveguide in an excessive way.

As shown as well in FIG. 22, over a horizontal range D between two opposing intersections between the electrically conductive coating 44 and one of the at least one electrically conductive layer structure 41 at the bottom of the recess 43, a height d1, d2 of the recess 43 does not vary substantially. More specifically, it is preferred that d1 and d2 do not deviate from each other by more than 20%, and most preferably by not more than 10%. Consequently, well-defined and homogeneous RF properties of the waveguide may be ensured.

Advantageously, a locally thickened metallic region 176 is formed as an intersection between the electrically conductive coating 44 and one of the at least one electrically conductive layer structure 41 at the bottom of the recess 43. Locally thickening metal at the shown critical region may function as a reinforcing structure capable of taking up forces acting on the constituents of the component carrier 100 during a lamination process.

Further advantageously, the electrically conductive coating 44 is substantially S-shaped at each of the sidewalls 110. Such an S-shaped copper structure may function in an analogous way as a leaf spring for damping forces during the manufacturing process.

In a nutshell, the structural features described referring to FIG. 21 and FIG. 22 may be obtained by recess formation by laser cutting in combination with metal deposition by plating, while appropriately setting the process parameters. The smooth sidewalls obtained during laser cutting ensure low loss RF signal transmission. At the same time, the mentioned structural features allow a fine-tuning of the high-frequency properties as well as a mechanically robust configuration preventing damage during manufacture.

Still referring to the embodiments of FIG. 20 and FIG. 21, edges 67 at an upper side (and additionally or alternatively at a lower side) of the recess 43 may comprise a metal-metal oxide-metal succession, more specifically a copper-copper oxide-copper succession. Hence, an oxide layer may be formed between two connected metal layers which may suppress the formation of grain boundaries in between.

It should be noted that the term “comprising” does not exclude other elements or steps and the article “a” or “an” does not exclude a plurality. Also, elements described in association with different embodiments may be combined.

Implementation of the disclosure is not limited to the preferred embodiments shown in the figures and described above. Instead, a multiplicity of variants are possible which variants use the solutions shown and the principle according to the disclosure even in the case of fundamentally different embodiments.

1. A component carrier, comprising:
a stack comprising at least one electrically conductive layer structure and at least one electrically insulating layer structure; and
a recess for example a cavity, being at least partially formed in the stack, optionally having an electrically conductive coating, and being configured as a waveguide;
wherein a plurality of edges delimiting the recess are formed by electrically conductive material of the at least one electrically conductive layer structure and/or of the optional electrically conductive coating.

2. The component carrier according to claim 1, comprising at least one of the following features:
wherein all vertical edges delimiting the recess are formed by electrically conductive material of the at least one electrically conductive layer structure and/or of the electrically conductive coating;
wherein all edges delimiting the recess are formed by electrically conductive material of the at least one electrically conductive layer structure and/or of the electrically conductive coating;
wherein at least two sidewalls of the recess are completely covered with electrically conductive material of the at least one electrically conductive layer structure and/or of the electrically conductive coating;
wherein at least one of a top wall, a bottom wall, and at least one sidewall of the recess is or are partially or completely covered with electrically conductive material of the at least one electrically conductive layer structure and/or of the electrically conductive coating;
wherein the recess is completely surrounded by electrically conductive material of the at least one electrically conductive layer structure and/or of the electrically conductive coating with the only exception of at least one opening for feeding a signal;
wherein at least one edge, for example at an upper side and/or at a lower side of the recess, comprises a metal-metal oxide-metal succession.

3.-8. (canceled)

9. The component carrier according to claim 1, wherein
a width of the recess varies along a length of the recess by not more than 75 μm.

10. The component carrier according to claim 1, comprising at least one of the following features:
wherein the width of the recess varies along the length of the recess by not more than 20 μm, for example by not more than 15 μm;
wherein the width is smaller than the length.

11. (canceled)

12. The component carrier according to claim 1, wherein the stack has a sidewall, delimiting the recess, which has a roughness Rz of not more than 75 μm, for example in a range from 15 μm to 75 μm.

13. The component carrier according to claim 1, comprising at least one of the following features:
wherein at least part of the sidewall is covered with an electrically conductive coating;
wherein at least one of the at least one electrically conductive layer structure is exposed at at least part of the sidewall;
wherein the sidewall extends continuously in a vertical direction;
wherein the sidewall has at least one step.

14. (canceled)

15. The component carrier according to claim 1, comprising at least one of the following features:
wherein at least one of the at least one electrically conductive layer structure defines a bottom of the recess;
wherein the at least one electrically conductive layer structure defining the bottom of the recess is a patterned layer, patterned in the region of the bottom of the recess;
wherein an uppermost of the at least one electrically conductive layer structure is a patterned layer;
a frequency filter structure in the recess and/or at material of the stack delimiting the recess, wherein the frequency filter structure is formed by a plurality of webs of at least one of the at least one electrically insulating layer structure at at least part of the sidewall, and by an electrically conductive structure formed on and/or between the webs;
wherein a horizontal surface of at least one of the at least one electrically conductive layer structure has a roughness Rz of not more than 1 μm, for example of not more than 0.5 μm, for example of not more than 0.2 μm;
an antenna structure in the recess and/or at material of the stack delimiting the recess,
wherein the antenna structure is a free-standing structure in the recess, is circumferentially spaced with respect to surrounding material of the stack by a gap, and comprises part of at least one of the at least one electrically conductive layer structure.

16.-24. (canceled)

25. A method of manufacturing a component carrier, the method comprising:
providing a stack comprising at least one electrically conductive layer structure and at least one electrically insulating layer structure;
forming a recess at least partially in the stack, wherein a width of the recess varies along a length of the recess by not more than 75 μm; and
configuring said recess (43) as a waveguide.

26. The method according to claim 25, wherein the method comprises:
forming a poorly adhesive structure in an interior of the stack;
forming a circumferentially closed trench in the stack extending up to the poorly adhesive structure; and
removing a material piece, delimited by the trench and the poorly adhesive structure, from the stack.

27. The method according to claim 26, comprising at least one of the following features:
wherein the method comprises forming the trench by laser cutting, for example by pulsed laser cutting, for example using a picosecond laser or a femtosecond laser;
wherein the method comprises forming a laser stop structure in the stack adjacent to the poorly adhesive structure;
wherein the method comprises forming a further poorly adhesive structure in an interior of the stack: forming a further circumferentially closed trench in the stack extending up to the further poorly adhesive structure, the further circumferentially closed trench having another diameter and/or depth than and/or being laterally displaced with respect to the circumferentially closed trench; and removing a further material piece, delimited by the further trench and the further poorly adhesive structure, from the stack.

28.-29. (canceled)

30. The component carrier according to claim 1, further comprising:
a wiring structure forming part of the at least one electrically conductive layer structure and being arranged on top of said recess; and
a ridge surrounding the recess, wherein the wiring structure is electrically coupled with the waveguide via the ridge.

31. The component carrier according to claim 30, comprising at least one of the following features:
an electrically conductive lining on at least part of the ridge and electrically coupling the waveguide with the wiring structure;
wherein for example the electrically conductive lining circumferentially surrounds the ridge;
wherein the ridge is a ring with a central through hole aligned with the recess;
wherein the ridge comprises an electrically insulating material;
wherein the wiring structure is located on top of the ridge;
wherein the wiring structure is the uppermost of the at least one electrically conductive layer structure;
an at least partially dielectric layer having a central through hole accommodating the ridge and having substantially the same height as the ridge plus electrically conductive material on the ridge;
wherein the wiring structure comprises a feedline structure for coupling a signal between the wiring structure and the waveguide.

32.-40. (canceled)

41. The component carrier, in particular according to claim 1, wherein at least one of the at least one electrically insulating layer structure is made of a poorly adhesive structure;
a metallic electroless plating structure formed on a surface of the stack apart from the poorly adhesive structure; and
wherein the poorly adhesive structure covers a bottom and/or at least one sidewall of the recess, and wherein the metallic electroless plating structure is formed on at least part of a sidewall of the stack delimiting the recess.

42. The component carrier according to claim 41, comprising at least one of the following features:
wherein the poorly adhesive structure is made of a hydrophobic material;
wherein the recess is configured as a waveguide;
wherein at least one of the at least one electrically conductive layer structure comprises a patterned metal layer at the bottom of the recess under the poorly adhesive structure.

43.-47. (canceled)

48. The component carrier according to claim 1, further comprising:
an electrically conductive coating on at least part of sidewalls of the stack which laterally delimit the recess;
wherein the electrically conductive coating is curved outwardly on an upper end of the sidewalls.

49. The component carrier according to claim 48, comprising at least one of the following features:
wherein a beak-shaped extension of the recess is formed between the electrically conductive coating and one of the at least one electrically conductive layer structure at the upper end of the sidewalls;
wherein the recess is delimited at a lower end of the sidewalls by a tilted metallic section formed in an interface region between the electrically conductive coating and one of the at least one electrically conductive layer structure;
wherein the electrically conductive coating tapers downwardly in a central part of the sidewalls;
wherein, over a horizontal range between two opposing intersections between the electrically conductive coating and one of the at least one electrically conductive layer structure at the bottom of the recess, a height of the recess varies by not more than 20%, for example by not more than 10%;
wherein a locally thickened metallic region is formed as an intersection between the electrically conductive coating and one of the at least one electrically conductive layer structure at the bottom of the recess;
wherein the electrically conductive coating is substantially S-shaped at at least one of the sidewalls.

50.-55. (canceled)

56. A component carrier, comprising:
a stack comprising at least one electrically conductive layer structure and at least one electrically insulating layer structure;
a recess being at least partially formed in the stack; and
a structured metallic electroless plating structure formed at least partially on at least one sidewall of the stack.

57. The component carrier according to claim 56, comprising at least one of the following features:
a structured poorly adhesive structure on said at least one sidewall apart from the structured metallic electroless plating structure;
wherein the recess is configured as a waveguide.

58.-60. (canceled)

61. A method of using a component carrier for a high-frequency application, the method comprising:
providing a stack comprising at least one electrically conductive layer structure and at least one electrically insulating layer structure;
forming a recess at least partially in the stack, optionally having an electrically conductive coating, and being configured as a waveguide;
wherein a plurality of edges delimiting the recess are formed by electrically conductive material of the at least one electrically conductive layer structure and/or of the optional electrically conductive coating; and
coupling a signal to the waveguide.

62. The method according to claim 61, comprising at least one of the following features:
wherein the component carrier is used for wireless communication, it for example according to 5G or 6G;
wherein the component carrier is used for high-frequency applications above 1 GHz, for example above 28 GHz.
